(19) United States
(12) Patent Application Publication
(10) Pub. No.: US 2025/0107394 A1
(43) Pub. Date: Mar. 27, 2025

(54) DISPLAY DEVICE

(71) Applicant: Samsung Display Co., Ltd., Yongin-si (KR)

(72) Inventors: HYEONJEONG IM, Yongin-si (KR); HYOMIN KO, Yongin-si (KR)

(21) Appl. No.: 18/738,654

(22) Filed: Jun. 10, 2024

(30) Foreign Application Priority Data
Sep. 25, 2023 (KR) 10-2023-0127967

(51) Int. Cl. H10K 59/80; H10K 50/13; H10K 50/15; H10K 50/16; H10K 59/122; H10K 59/38; H10K 102/00; H10K 102/10

(52) U.S. Cl. CPC H10K 59/80518; H10K 50/13; H10K 50/156; H10K 50/166; H10K 59/122; H10K 59/38; H10K 2102/101; H10K 2102/351

(57) ABSTRACT

A display device includes a base layer including a first pixel area, a second pixel area adjacent to the first pixel area, and a third pixel area adjacent to the second pixel area, wherein each of the first pixel area, the second pixel area and the third pixel area include: a first electrode on the base layer and including a reflective layer, a first light emitting layer on the first electrode and to generate a blue light, a second light emitting layer on the first electrode and to generate a green light, a third light emitting layer on the first light emitting layer and the second light emitting layer and to generate a red light, and a second electrode on the third light emitting layer.

### CROSS-REFERENCE TO RELATED APPLICATION

The present application claims priority to and the benefit of Korean Patent Application No. 10-2023-0127967, filed on Sep. 25, 2023, the entire content of which is hereby incorporated by reference.

### BACKGROUND

### 1. Field

Embodiments of the present disclosure relate to a display device. For example, embodiments of the present disclosure relate to a display device with improved reliability.

### 2. Description of the Related Art

Display devices are utilized in various electronic devices such as smartphones, televisions, computers, and/or the like.

The display device may include red, green, and blue pixels to display colors. A method of utilizing a shadow mask is mainly or substantially utilized to form a light emitting layer in each pixel, however, defects such as sagging of the mask may occur in the shadow mask method, and thus, a process of commonly forming a light emitting layer and an organic layer over all the pixels utilizing an open mask is being pursued and/or developed.

However, in the case where the organic layer is commonly formed, a lateral leakage current may flow through the organic layer, and as a result, even unwanted pixels may emit lights, resulting in color mixing and/or poor luminance.

### SUMMARY

Aspects of one or more embodiments of the present disclosure relate to a display device capable of blocking lateral leakage current between adjacent pixels and preventing or reducing color mixing and deterioration in luminescence, thus helping to secure the reliability of the display device.

Aspects of one or more embodiments of the present disclosure relate to a display device including a light emitting element whose optical length is improved or optimized for each pixel area and having an excellent or suitable light emission efficiency.

Additional aspects will be set forth in part in the description which follows and, in part, will be apparent from the description, or may be learned by practice of the presented embodiments of the disclosure.

One or more embodiments of the present disclosure provide a display device including a base layer including a first pixel area, a second pixel area adjacent to the first pixel area, and a third pixel area adjacent to the second pixel area, wherein each of the first pixel area, the second pixel area and the third pixel area include: a first electrode on the base layer and including a reflective layer, a first light emitting layer on the first electrode and to generate a blue light, a second light emitting layer on the first electrode and to generate a green light, a third light emitting layer on the first light emitting layer and the second light emitting layer and to generate a red light, and a second electrode on the third light emitting layer. A distance from a lower surface of the second electrode to an upper surface of the reflective layer is defined as an optical length. The optical length in the first pixel area is an (n+2)th-order resonance thickness of the blue light, the optical length in the second pixel area is an (n+1)th-order resonance thickness of the green light, and the optical length in the third pixel area is an nth-order resonance thickness of the red light. The n is an integer equal to or greater than 1.

In one or more embodiments, at least one of the first electrode of the first pixel area, the first electrode of the second pixel area or the first electrode of the third pixel area may further include a first conductive layer under the reflective layer and a second conductive layer on the reflective layer.

In one or more embodiments, each of the first and second conductive layers may include a transparent conductive oxide.

In one or more embodiments, the second light emitting layer may be on the first light emitting layer.

In one or more embodiments, a distance from the first light emitting layer to the reflective layer in the first pixel area may be equal to or greater than about 1350 angstroms and may be equal to or smaller than about 1550 angstroms.

In one or more embodiments, a distance from the second light emitting layer to the reflective layer in the second pixel area may be equal to or greater than about 2200 angstroms and may be equal to or smaller than about 2400 angstroms.

In one or more embodiments, the n may be 5 and a distance from the third light emitting layer to the reflective layer in the third pixel area may be equal to or greater than about 7350 angstroms and equal to or smaller than about 7550 angstroms.

In one or more embodiments, the n may be 4 and a distance from the third light emitting layer to the reflective layer in the third pixel area is equal to or greater than about 5650 angstroms and equal to or smaller than about 5850 angstroms. In one or more embodiments, the first light emitting layer may be on the second light emitting layer, the n may be 5, a distance from the first light emitting layer to the reflective layer in the first pixel area may be equal to or greater than about 2660 angstroms and may be equal to or smaller than about 2860 angstroms, a distance from the second light emitting layer to the reflective layer in the second pixel area may be equal to or greater than about 1860 angstroms and may be equal to or smaller than about 2060 angstroms.

In one or more embodiments, the distance from the third light emitting layer to the reflective layer in the third pixel area may be equal to or greater than about 7400 angstroms and may be equal to or smaller than about 7600 angstroms.

Embodiments of the present disclosure include a display device including a base layer including a pixel area and a non-pixel area adjacent to the pixel area, a circuit element layer on the base layer, and a display element layer on the circuit element layer and including a pixel definition layer in which a groove portion is defined and a light emitting element, wherein at least a portion of the light emitting element is on the pixel definition layer. The light emitting element includes a first electrode, a first light emitting stack] on the first electrode, a second light emitting stack on the first electrode, a lower charge generation layer between the first light emitting stack and the second light emitting stack, a third light emitting stack on the first light emitting stack and the second light emitting stack, an upper charge generation layer between the second light emitting stack and the third light emitting stack, and a second electrode on the upper charge generation layer. The second electrode and the second charge generation layer are spaced and/or apart (e.g., spaced apart or separated) from each other with the third light emitting stack interposed therebetween in an area overlapping the groove portion. The second electrode is entirely over each of (e.g., is substantially continuous across) the pixel area and the non-pixel area.

In one or more embodiments, the third light emitting stack may have a thickness greater than a thickness of the first light emitting stack and greater than a thickness of the second light emitting stack.

In one or more embodiments, the upper charge generation layer may include a first upper portion and a second upper portion in the non-pixel area, and the first upper portion and the second upper portion may be spaced and/or apart (e.g., spaced apart or separated) from each other with an area where at least a portion of the first upper portion or the second upper portion overlap the groove portion interposed therebetween.

In one or more embodiments, the lower charge generation layer may include a first lower portion and a second lower portion in the non-pixel area, and the first lower portion and the second lower portion may be spaced and/or apart (e.g., spaced apart or separated) from each other with an area where at least a portion of the first lower portion or the second lower portion overlap the groove portion interposed therebetween.

In one or more embodiments, at least one pore may be defined in the first light emitting stack or the second light emitting stack, and an area where the pore is defined at least may partially overlap the area where the groove portion is defined.

In one or more embodiments, at least a portion of the pore may be defined between the first lower portion and the second lower portion.

In one or more embodiments, at least a portion of a side surface of each of the first lower portion and the second lower portion may be exposed through (e.g., may define) the pore.

In one or more embodiments, the pixel area may include a first pixel area, a second pixel area adjacent to the first pixel area, and a third pixel area adjacent to the second pixel area.

In one or more embodiments, the first electrode may include a first conductive layer, a reflective layer on the first conductive layer, a second conductive layer on the reflective layer, and an optical auxiliary layer at (e.g., arranged in, on, or with) at least a portion between the reflective layer and the second conductive layer and the optical auxiliary layer may include a second optical auxiliary layer overlapping the second pixel area and a third optical auxiliary layer overlapping the third pixel area.

In one or more embodiments, the second light emitting stack may be arranged on the first light emitting stack.

In one or more embodiments, the second optical auxiliary layer may have a thickness equal to or greater than about 400 angstroms and equal to or smaller than about 500 angstroms.

In one or more embodiments, the third optical auxiliary layer may have a thickness equal to or greater than about 150 angstroms and equal to or smaller than about 250 angstroms.

In one or more embodiments, a distance from the upper charge generation layer to the second electrode may be equal to or greater than about 5150 angstroms and equal to or smaller than about 5350 angstroms.

In one or more embodiments, the first light emitting stack may be on the second light emitting stack.

In one or more embodiments, the second optical auxiliary layer may have a thickness equal to or greater than about 400 angstroms and equal to or smaller than about 600 angstroms.

In one or more embodiments, the third optical auxiliary layer may have a thickness equal to or greater than about 200 angstroms and equal to or smaller than about 400 angstroms.

In one or more embodiments, a distance from the upper charge generation layer to the second electrode may be equal to or greater than about 4350 angstroms and equal to or smaller than about 4450 angstroms.

In one or more embodiments, the second light emitting stack may be on the first light emitting stack.

In one or more embodiments, the first electrode may include a first conductive layer, an optical auxiliary layer on the first conductive layer, and a second conductive layer on the optical auxiliary layer.

In one or more embodiments, the optical auxiliary layer may include a first optical auxiliary layer overlapping the first pixel area and a second optical auxiliary layer overlapping the second pixel area.

In one or more embodiments, the first optical auxiliary layer may have a thickness equal to or greater than about 200 angstroms and equal to or smaller than about 400 angstroms.

In one or more embodiments, the second optical auxiliary layer may have a thickness equal to or greater than about 500 angstroms and equal to or smaller than about 700 angstroms.

In one or more embodiments, a distance from the upper charge generation layer to the second electrode may be equal to or greater than about 3850 angstroms and equal to or smaller than about 4150 angstroms.

In one or more embodiments, the display device may further include a color filter layer on the second electrode, the color filter layer may include a first color filter overlapping the first pixel area and to transmit a blue light, a second color filter overlapping the second pixel area and to transmit a green light, and a third color filter overlapping the third pixel area and to transmit a red light.

In one or more embodiments, the first light emitting stack may include a first light emitting layer, a first hole transport layer, and a first electron transport layer spaced and/or apart (e.g., spaced apart or separated) from the first hole transport layer with the first light emitting layer interposed therebetween.

In one or more embodiments, the second light emitting stack may include a second light emitting layer, a second hole transport layer, and a second electron transport layer spaced and/or apart (e.g., spaced apart or separated) from the second hole transport layer with the second light emitting layer interposed therebetween.

In one or more embodiments, the third light emitting stack may include a third light emitting layer, a third hole transport layer, and a third electron transport layer spaced and/or apart (e.g., spaced apart or separated) from the third hole transport layer with the third light emitting layer interposed therebetween.

In one or more embodiments, the third hole transport layer may have a thickness greater than a thickness of the second hole transport layer and a thickness of the first hole transport layer.

In one or more embodiments, the light emitting element may be to emit a white light.

According to the above, a lateral leakage current may be blocked from flowing between pixels adjacent to each other, and color mixing and deterioration in luminescence may be prevented or reduced.

### BRIEF DESCRIPTION OF THE DRAWINGS

The above and other aspects, features, and/or principles of embodiments of the present disclosure will become readily apparent by reference to the following detailed description when considered in conjunction with the accompanying drawings wherein:

FIG. 1 is an assembled perspective view of an electronic device according to one or more embodiments of the present disclosure;

FIG. 2 is an exploded perspective view of an electronic device according to one or more embodiments of the present disclosure;

FIG. 3 is a cross-sectional view of a display module according to one or more embodiments of the present disclosure;

FIG. 4 is a cross-sectional view of a display area of a display panel according to one or more embodiments of the present disclosure;

FIG. 5 is a cross-sectional view of a display panel in a display area according to one or more embodiments of the present disclosure;

FIGS. 6A-6C are each a cross-sectional view showing portions of a display panel according to one or more embodiments of the present disclosure;

FIGS. 7A-7C are each a cross-sectional view showing portions of a display panel according to one or more embodiments of the present disclosure; and

FIGS. 8A-8C are each a cross-sectional view showing portions of a display panel according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In addition, it will also be understood that when an element is referred to as being “between” two elements, it can be the only element between the two elements, or one or more intervening elements may also be present.

Unless otherwise noted, like numerals refer to like elements throughout, and duplicative descriptions thereof may not be provided. In the drawings, the thickness, ratio, and dimensions of components may be exaggerated for clarity and/or effective description of the technical content. As used herein, the term “and/or” may include any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms, “a”, “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification and should not be interpreted in an idealized or overly formal sense, unless expressly so defined herein.

Hereinafter, embodiments of the present disclosure will be described with reference to accompanying drawings.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

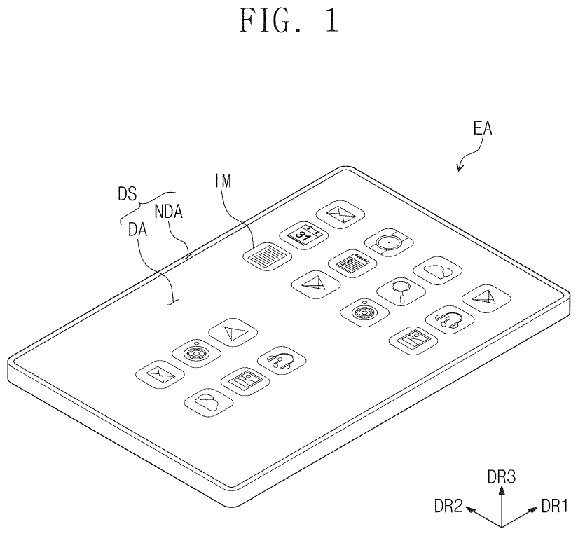

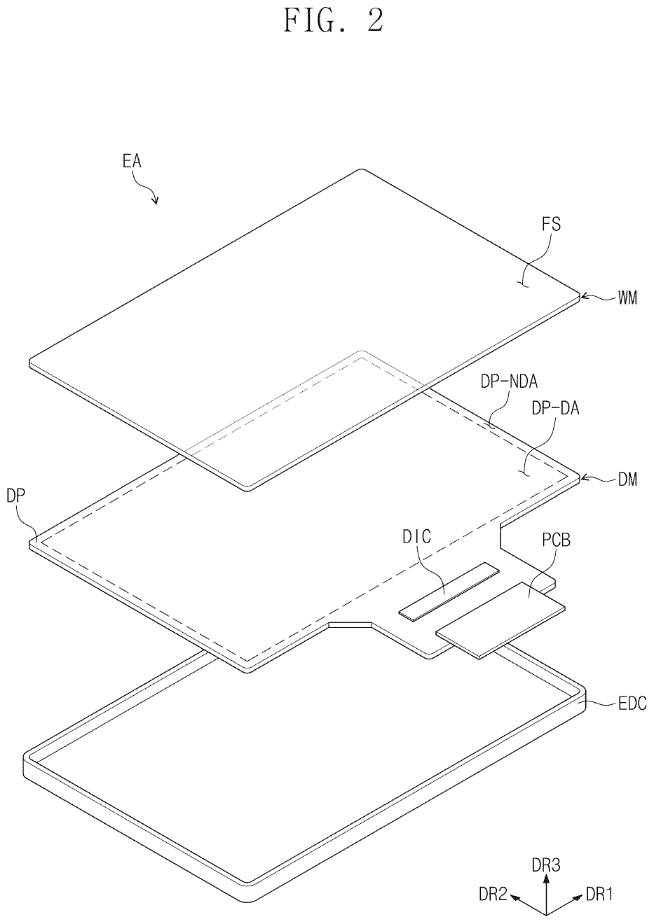

FIG. 1 is an assembled perspective view of an electronic device EA according to one or more embodiments of the present disclosure. FIG. 2 is an exploded perspective view of the electronic device EA according to one or more embodiments of the present disclosure.

Referring to FIG. 1, the electronic device EA may be activated in response to electrical signals. The electronic device EA may display an image IM and may sense an external input. The electronic device EA may include one or more suitable embodiments. For example, the electronic device EA may be a mobile phone, a foldable mobile phone, a notebook computer, a television set, a tablet computer, a car navigation unit, a game unit, or a relatively high-resolution wearable unit, however, these are merely examples. The wearable unit may be an electronic device that is worn on the body of a user and may include a head-mounted display (HMD) that enables an extended reality (XR).

In FIG. 1, the tablet computer is shown as the electronic device EA, however, the present disclosure should not be limited thereto or thereby. The electronic device may be a smartphone or a large-sized display device, such as a notebook computer, a monitor, or a television set.

The electronic device EA may display the image IM through a display surface DS, which is substantially parallel to each of a first direction DR1 and a second direction DR2, and which has a thickness in a third direction DR3. The display surface DS through which the image IM is displayed may correspond to a front surface of the electronic device EA and a front surface FS of a window WM (see, e.g., FIG. 2). Hereinafter, the display surface, the front surface of the electronic device EA, and the front surface of the window WM (see, e.g., FIG. 2) will be assigned with the same reference numeral (e.g., front surface FS). The image IM may include a still image as well as a video. FIG. 1 shows a plurality of application icons as a representative example of the image IM.

In one or more embodiments, front (or upper) and rear (or lower) surfaces of each member of the electronic device EA may be defined with respect to a direction in which the image IM is displayed. The front and rear surfaces may be opposite to (e.g., facing oppositely away from) each other in the third direction DR3, and a normal line direction of each of the front and rear surfaces may be substantially parallel to the third direction DR3. A separation distance in the third direction DR3 between the front surface and the rear surface may correspond to a thickness of the electronic device EA in the third direction DR3. In one or more embodiments, directions indicated by the first, second, and third directions DR1, DR2, and DR3 may be relative to each other and may be changed to other directions. In the following descriptions, the expression “if (e.g., when) viewed in a plane” or “in a plan view” may refer to a state of being viewed on the plane defined by the first direction DR1 and the second direction DR2.

The electronic device EA may sense a user input applied thereto from the outside. The user input may include one or more suitable types (kinds) of external inputs, such as touch by a part of the user's body, light, heat, or pressure. The user input may be provided in one or more suitable ways, and the electronic device EA may sense the user input applied to a side or rear surface of the electronic device EA depending on its structure; however, the present disclosure is not limited thereto.

As shown in FIG. 2, the electronic device EA may include the window WM, a display module DM, and an external case EDC. In one or more embodiments, the window WM may be coupled with the external case EDC to form (or provide) an exterior of the electronic device EA. The external case EDC, the display module DM, and the window WM may be sequentially stacked in the third direction DR3.

The window WM may include an optically transparent material. The window WM may include an insulating panel. As an example, the window WM may include a glass, plastic, or combination thereof.

As described above, the front surface FS of the window WM may define the front surface of the electronic device EA.

The window WM may include a bezel area and a transmissive area. The transmissive area may be an optically transparent area. For example, the transmissive area may have a transmittance of about 90% or more with respect to a visible light.

The bezel area may have a light transmittance relatively lower than that of the transmissive area. The bezel area may define a shape of the transmissive area. The bezel area may be defined adjacent to the transmissive area and may be around (e.g., surround) the transmissive area. The bezel area may have a set or predetermined color. The bezel area may overlap a non-display area DP-NDA of a display panel DP described in more detail later. The bezel area may cover the non-display area DP-NDA of the display panel DP to prevent or substantially prevent the non-display area DP-NDA from being viewed from the outside; however, this is merely an example. According to one or more embodiments, the bezel area may not be provided from the window WM.

The display module DM may include at least the display panel DP. FIG. 2 shows only the display panel DP among components of the display module DM, however, the display module DM may further include a plurality of components arranged on and under the display panel DP. The detailed stack structure of the display module DM will be described in more detail later.

The display panel DP may include a display area DP-DA and the non-display area DP-NDA, which respectively correspond to a display area DA (see, e.g., FIG. 1) and a non-display area NDA (see, e.g., FIG. 1) of the electronic device EA. In the present disclosure, the expression “An area/portion corresponds to another area/portion.” means that “An area/portion overlaps another area/portion.”, however, the “areas and portions” should not be limited to having the same size as each other.

The display module DM may include a driving chip DIC arranged in the non-display area DP-NDA. The display module DM may further include a printed circuit board PCB coupled with the display panel DP in the non-display area DP-NDA. The printed circuit board PCB may be electrically connected to pads arranged in the non-display area DP-NDA of the display panel DP by an anisotropic adhesive layer.

The driving chip DIC may include driving elements to drive pixels of the display panel DP, e.g., a data driving circuit. FIG. 2 shows a structure in which the driving chip DIC is mounted on the display panel DP, however, the present disclosure should not be limited thereto or thereby. As an example, the driving chip DIC may be mounted on the printed circuit board PCB.

The external case EDC may accommodate the display module DM and may be coupled with the window WM. The external case EDC may protect or substantially protect components accommodated therein, such as the display module DM.

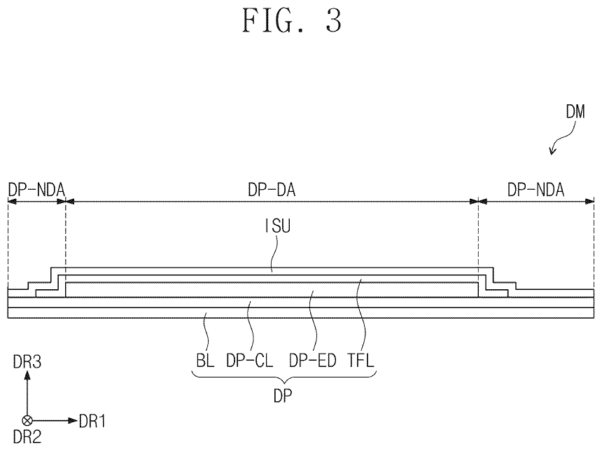

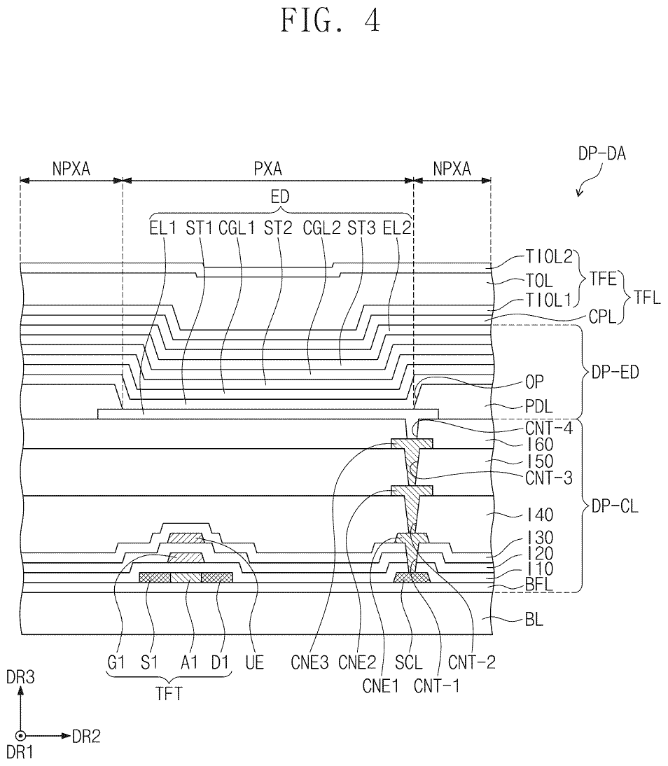

FIG. 3 is a cross-sectional view of the display module DM according to one or more embodiments of the present disclosure. FIG. 4 is a cross-sectional view of the display area DP-DA of the display panel DP according to one or more embodiments of the present disclosure.

Referring to FIG. 3, the display module DM may include the display panel DP and an input sensing unit ISU.

The display panel DP may have configurations/structures to generate the image IM (see, e.g., FIG. 1). The image IM (see, e.g., FIG. 1) generated by the display panel DP may be viewed from the outside by the user through the display area DA (see, e.g., FIG. 1).

The display panel DP may be a light-emitting type or kind display panel, however, the present disclosure is not limited thereto or thereby. For instance, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED. Hereinafter, the organic light emitting display panel will be described as a representative example of the display panel DP.

The display panel DP may include a base layer BL, a circuit element layer DP-CL arranged on the base layer BL, a display element layer DP-ED arranged on the circuit element layer DP-CL, and an upper insulating layer TFL arranged on the display element layer DP-ED. Components included in the display panel DP will be described in more detail with reference to FIG. 4.

The input sensing unit ISU may be arranged on the display panel DP. The input sensing unit ISU may sense the external input applied thereto from the outside. The external input may include a variety of inputs provided from the outside of the electronic device EA (see, e.g., FIG. 1). As an example, the external inputs may include a proximity input (e.g., an input that detects hovering), which detects an external input when an object approaches close to or adjacent to the electronic device EA at a set or predetermined distance, as well as a touch input, which detects touch by a part of the user's body (e.g., the user's hand). In one or more embodiments, the external inputs may be provided in the form of force, pressure, light, and/or the like, but the present disclosure is not limited thereto or thereby.

The input sensing unit ISU may be formed on the display panel DP through/by one or more successive processes. In this case, the input sensing unit ISU may be arranged directly on the display panel DP. In the following descriptions, the expression “A component B is arranged directly on a component A.” means that no intervening elements are present between the component B and the component A. For example, a separate adhesive member may not be arranged between the input sensing unit ISU and the display panel DP.

In one or more embodiments, the display module DM may further include a protective member arranged on a lower surface of the display panel DP and an anti-reflective member arranged on an upper surface of the input sensing unit ISU. The anti-reflective member may reduce a reflectance of the display module DM with respect to external light. The anti-reflective member may be arranged directly on the input sensing unit ISU through/by one or more successive processes.

Referring to FIG. 4, the display panel DP (see, e.g., FIG. 3) may include the base layer BL, the circuit element layer DP-CL, the display element layer DP-ED, and the upper insulating layer TFL. The circuit element layer DP-CL, the display element layer DP-ED, and the upper insulating layer TFL may be arranged on the base layer BL. A transistor TFT is shown as a driving circuit of each pixel. For the convenience of explanation, FIG. 4 shows only one transistor TFT in a cross-section of the display panel DP; however, the display panel DP (see, e.g., FIG. 3) may further include other transistors in addition to the transistor TFT.

The base layer BL may provide a base surface on which the circuit element layer DP-CL, the display element layer DP-ED, and the upper insulating layer TFL are stacked. The base layer BL may be a rigid substrate or a flexible substrate that is bendable, foldable, or rollable. The base layer BL may be a glass substrate, a metal substrate, or a polymer substrate; however, the present disclosure is not limited thereto or thereby. According to one or more embodiments, the base layer BL may include an inorganic layer, an organic layer, or a composite material layer.

The base layer BL may have a multi-layer structure. For instance, the base layer BL may include a first synthetic resin layer, an inorganic layer having a single-layer or multi-layer structure, and a second synthetic resin layer arranged on the inorganic layer having a single-layer or multi-layer structure. Each of the first and second synthetic resin layers may include a polyimide-based resin, however, the present disclosure is not limited thereto or thereby.

The circuit element layer DP-CL may include a buffer layer BFL and a plurality of insulating layers including first, second, third, fourth, fifth, and sixth insulating layers 110, 120, 130, 140, 150, and 160, however, the present disclosure is not limited thereto or thereby. In one or more embodiments, the buffer layer BFL may not be provided, one or more layers of the first, second, third, fourth, fifth, and sixth insulating layers 110, 120, 130, 140, 150, and 160 may not be provided, or the circuit element layer DP-CL may further include other insulating layers.

The buffer layer BFL may be arranged on the base layer BL. The buffer layer BFL may improve an adhesive force between a semiconductor pattern and the base layer BL or between a connection pattern and the base layer BL. The buffer layer BFL may include a silicon oxide layer and a silicon nitride layer. In one or more embodiments, the silicon oxide layer and the silicon nitride layer may be alternately stacked with each other. The circuit element layer DP-CL may further include a barrier layer arranged between the buffer layer BFL and the base layer BL.

A drain D1 (e.g., a drain electrode), an active A1 (e.g., an active electrode), and a source S1 (e.g., a source electrode) may be arranged on the buffer layer BFL. The drain D1, the active A1, and the source S1 may define the transistor TFT with a gate G1 (e.g., a gate electrode) described in more detail later. In a case where the display panel DP (see, e.g., FIG. 3) includes other transistors in addition to the transistor TFT, the other transistors may include a different material from the transistor TFT and may be arranged on a different layer from the transistor TFT. The drain D1, the active A1, and the source S1 may define the semiconductor pattern.

FIG. 4 shows a portion of a connection signal line SCL formed from the semiconductor pattern. In one or more embodiments, the connection signal line SCL may be connected to the drain D1 of the transistor TFT if (e.g., when) viewed in the plane (e.g., in a plan view).

The first insulating layer 110 may be arranged on the buffer layer BFL. The first insulating layer 110 may commonly overlap the pixels arranged in the display area DP-DA and may cover the semiconductor pattern. The first insulating layer 110 may be an inorganic layer and/or an organic layer and may have a single-layer or multi-layer structure. The first insulating layer 110 may include at least one of aluminum oxide, titanium oxide, silicon oxide, silicon oxynitride, zirconium oxide, and/or hafnium oxide. Not only the first insulating layer 110 but also an insulating layer of the circuit element layer DP-CL described in more detail later may be an inorganic layer and/or an organic layer and may have a single-layer or multi-layer structure.

The gate G1 may be arranged on the first insulating layer 110. The gate G1 may be a portion of a metal pattern. The gate G1 may overlap the active A1. The gate G1 may be utilized as a mask in a process of doping the semiconductor pattern.

The second insulating layer 120 may be arranged on the first insulating layer 110 and may cover the gate G1. The second insulating layer 120 may commonly overlap the pixels. An upper electrode UE may be arranged on the second insulating layer 120. The upper electrode UE may overlap the gate G1. The upper electrode UE may include a plurality of metal layers.

The third insulating layer 130 may be arranged on the second insulating layer 120 and may cover the upper electrode UE. A first connection electrode CNE1 may be arranged on the third insulating layer 130. The first connection electrode CNE1 may be connected to the connection signal line SCL via a contact hole CNT-1 defined through the first, second, and third insulating layers 110, 120, and 130.

The fourth insulating layer 140 may be arranged on the third insulating layer 130. The fourth insulating layer 140 may be an organic layer. A second connection electrode CNE2 may be arranged on the fourth insulating layer 140. The second connection electrode CNE2 may be connected to the first connection electrode CNE1 via a contact hole CNT-2 defined through the fourth insulating layer 140.

The fifth insulating layer 150 may be arranged on the fourth insulating layer 140. The fifth insulating layer 150 may be an organic layer. A third connection electrode CNE3 may be arranged on the fifth insulating layer 150. The third connection electrode CNE3 may be connected to the second connection electrode CNE2 via a contact hole CNT-3 defined through the fifth insulating layer 150.

The sixth insulating layer 160 may be arranged on the fifth insulating layer 150 and may cover the third connection electrode CNE3. The sixth insulating layer 160 may be an organic layer.

The display element layer DP-ED may include a pixel definition layer PDL and a light emitting element ED. The light emitting element ED may be arranged on the sixth insulating layer 160. The light emitting element ED may include a first electrode EL1, a first light emitting stack ST1, a lower charge generation layer CGL1, a second light emitting stack ST2, an upper charge generation layer CGL2, a third light emitting stack ST3, and a second electrode EL2, which are sequentially stacked.

In embodiments of the present disclosure, the lower charge generation layer CGL1 may be expressed as a ‘first charge generation layer’ and the upper charge generation layer CGL2 may be expressed as a ‘second charge generation layer’.

In one or more embodiments, FIG. 4 shows the structure in which the light emitting element ED includes three light emitting stacks ST1, ST2, and ST3 and two charge generation layers CGL1 and CGL2 arranged between the three light emitting stacks ST1, ST2, and ST3 as a representative example. However, the present disclosure is not limited thereto or thereby. According to one or more embodiments, the light emitting element ED may include four or more light emitting stacks.

The first electrode EL1 may be arranged on the sixth insulating layer 160. The first electrode EL1 may be connected to the third connection electrode CNE3 via a contact hole CNT-4 defined through the sixth insulating layer 160.

The first electrode EL1 may be a reflective electrode. As an example, the first electrode EL1 may include Ag, Mg, Cu, Al, Pt, Pd, Au, Ni, Nd, Ir, Cr, Li, Ca, LiF/Ca, LiF/Al, Mo, Ti, W, In, Zn, Sn, a compound thereof, and/or any suitable mixture thereof, e.g., a mixture of Ag and Mg, which has a relatively high reflectance.

According to one or more embodiments, the first electrode EL1 may have a multi-layer structure of a reflective layer, which is formed of the above-mentioned material, and a transparent conductive layer formed of indium tin oxide (ITO), indium zinc oxide (IZO), zinc oxide (ZnO), and/or indium tin zinc oxide (ITZO). As an example, the first electrode EL1 may have a two-layer structure of ITO/Ag or a three-layer structure of ITO/Ag/ITO, however, the present disclosure is not limited thereto or thereby. According to one or more embodiments, the first electrode EL1 may include the above-mentioned metal materials, a combination of two or more metal materials of (e.g., selected from among) the above-mentioned metal materials, or oxides of the above-mentioned metal materials. The first electrode EL1 may have a thickness within a range of about 70 nm to about 1000 nm. As an example, the thickness of the first electrode EL1 may be within a range of about 100 nm to about 300 nm.

The pixel definition layer PDL may be arranged on the sixth insulating layer 160 and may cover at least a portion of the first electrode EL1. A pixel opening OP may be defined through the pixel definition layer PDL. At least a portion of the first electrode EL1 may be exposed through the pixel opening OP of the pixel definition layer PDL.

The pixel definition layer PDL may include a silicon-based inorganic material. For example, the pixel definition layer PDL may include at least one of silicon nitride, silicon oxide, or silicon oxynitride.

The display area DP-DA may include a pixel area PXA and a non-pixel area NPXA adjacent to the pixel area PXA. The non-pixel area NPXA may be around (e.g., surround) the pixel area PXA. The pixel area PXA may be defined to correspond to the portion of the first electrode EL1, which is exposed through the pixel opening OP.

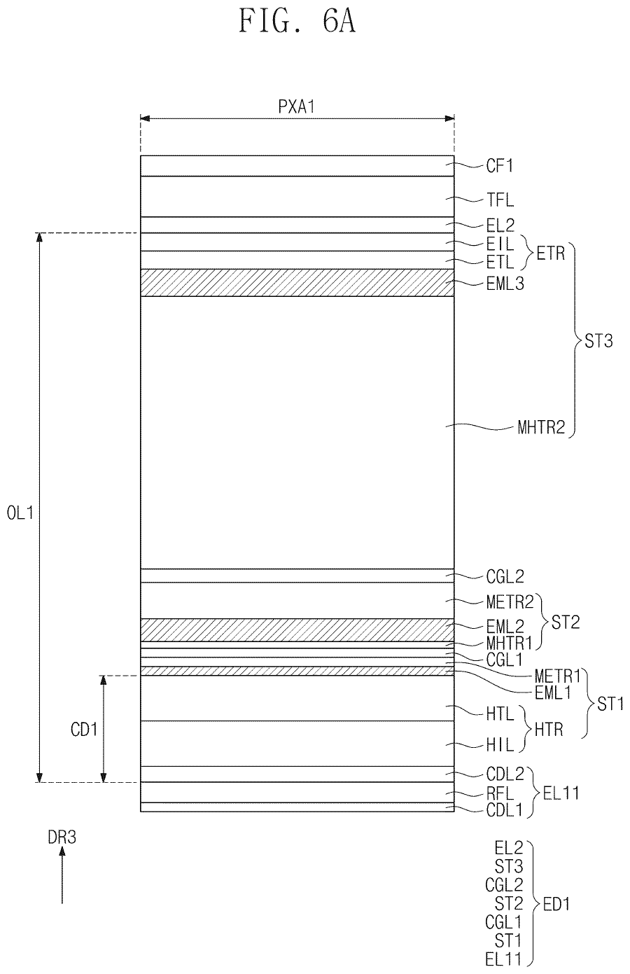

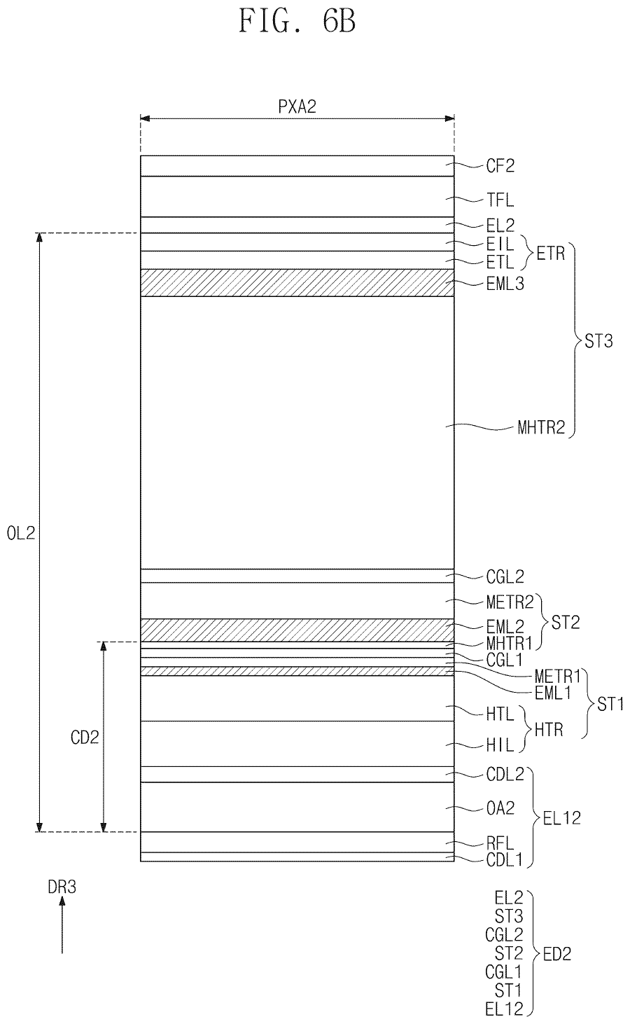

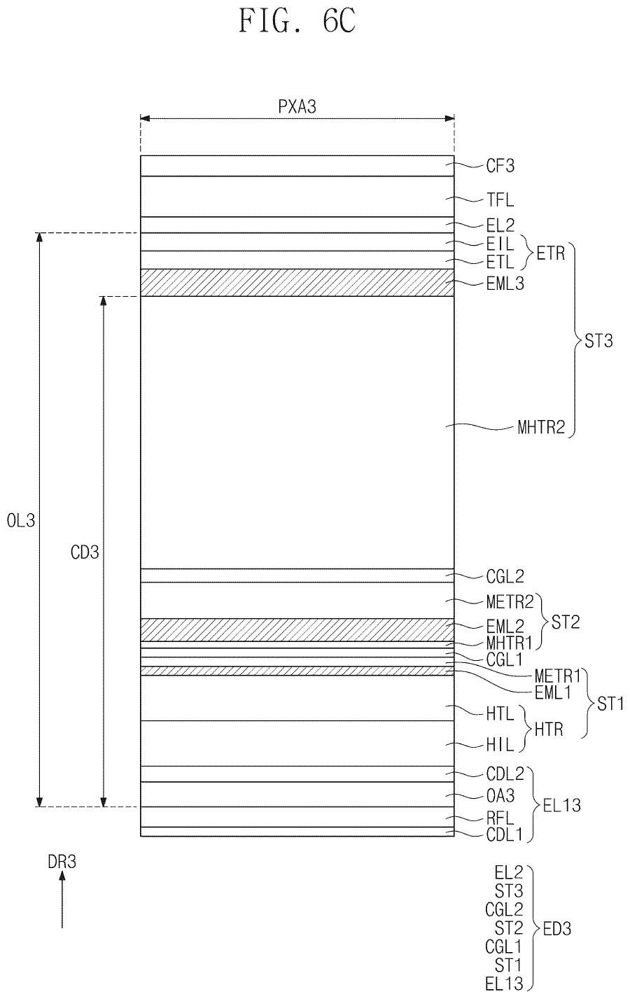

Each of the first, second, and third light emitting stacks ST1, ST2, and ST3 may include a light emitting layer. According to one or more embodiments, the first light emitting stack ST1 may include a first light emitting layer EML1 (see, e.g., FIG. 6A), the second light emitting stack ST2 may include a second light emitting layer EML2 (see, e.g., FIG. 6A), and the third light emitting stack ST3 may include a third light emitting layer EML3 (see, e.g., FIG. 6A). For example, the light emitting element including the light emitting stacks each being provided with the light emitting layer may be referred to as a light emitting element having a Tandem structure. The first, second, and third light emitting stacks ST1, ST2, and ST3 will be described in more detail with reference to FIG. 6A.

The light emitting stacks ST1, ST2, and ST3 may be to emit lights having the same wavelength as each other. As an example, the light emitted from each of the light emitting stacks ST1, ST2, and ST3 may be a blue light, however, the present disclosure should not be limited thereto or thereby. According to one or more embodiments, the lights emitted from the light emitting stacks ST1, ST2, and ST3 may have different wavelength ranges from each other. As an example, at least one of the light emitting stacks ST1, ST2, and/or ST3 may be to emit the blue light, and the other stacks of the light emitting stacks ST1, ST2, and ST3 may be to emit a green light. The light emitting element ED including the light emitting stacks ST1, ST2, and ST3 emitting lights having different wavelength ranges from each other may be to emit a white light.

The charge generation layers may be arranged between the light emitting stacks. The lower charge generation layer CGL1 may be arranged between the first light emitting stack ST1 and the second light emitting stack ST2, and the upper charge generation layer CGL2 may be arranged between the second light emitting stack ST2 and the third light emitting stack ST3.

When a voltage is applied, the charge generation layers CGL1 and CGL2 may form (or provide) a complex through an oxidation-reduction reaction, and thus may generate charges (electrons and holes). In one or more embodiments, the charge generation layers CGL1 and CGL2 may provide the generated charges to each of the light emitting stacks ST1, ST2, and ST3 adjacent thereto. The charge generation layers CGL1 and CGL2 may double the efficiency of current generated in the light emitting stacks ST1, ST2, and ST3 adjacent thereto and may adjust a balance of the charges between the light emitting stacks ST1, ST2, and ST3 adjacent to each other.

For the convenience of explanation, FIG. 4 shows the structure in which the light emitting stacks ST1, ST2, and ST3 and the charge generation layers CGL1 and CGL2 have the same thickness as each other, however, the light emitting stacks ST1, ST2, and ST3 and the charge generation layers CGL1 and CGL2 may have different thicknesses from each other, and this will be described in more detail later with reference to FIGS. 6A to 8C.

Each of the charge generation layers CGL1 and CGL2 may have a layer structure. As an example, each of the charge generation layers CGL1 and CGL2 may have a layer structure in which a p-type or kind charge generation (e.g., p-charge generation) layer and an n-type or kind charge generation (e.g., n-charge generation) layer are bonded to each other.

The n-type or kind charge generation layer may provide electrons to the stacks adjacent thereto. The n-type or kind charge generation layer may be obtained by doping a base material with an n-dopant. The p-type or kind charge generation layer may provide holes to the stacks adjacent thereto.

Each of the charge generation layers CGL1 and CGL2 may include an n-type or kind aryl amine-based material or a p-type or kind metal oxide. Each of the charge generation layers CGL1 and CGL2 may include a charge-generating compound containing an aryl amine-based organic compound, a metal, an oxide of a metal, a carbide, a fluoride, and/or any suitable mixture thereof.

As an example, the aryl amine-based organic compound may be n,n′-di(1-naphthyl)-n,n′-diphenyl-(1,1′-biphenyl)-4,4′-diamine (α-NPD), 4,4′,4″-tris(n-(naphthalen-2-yl)-n-phenyl-amino)-triphenylamine (2-TNATA), 1-n, 1-n-bis[4-(diphenylamino)phenyl]-4-n, 4-n-diphenylbenzene-1,4-diamine (TDATA), 4,4′,4″-tris[phenyl(m-tolyl)amino]triphenylamine (MTDATA), 2,2′,7,7′-tetrakis(N,N-diphenylamino)-9,9-spirobifluorene (spiro-TAD), or n,n′-bis(naphthalen-1-yl)-N,N′-bis(phenyl)-2,7-diamino-9,9-spirobifluorene (spiro-NPB). For example, the metal may be cesium (Cs), molybdenum (Mo), vanadium (V), titanium (Ti), tungsten (W), barium (Ba), or lithium (Li). Also, for example, the oxide of the metal, carbide, and/or fluoride may be Re₂O₇, MoO₃, V₂O₅, WO₃, TiO₂, Cs₂CO₃, BaF, LiF, and/or CsF.

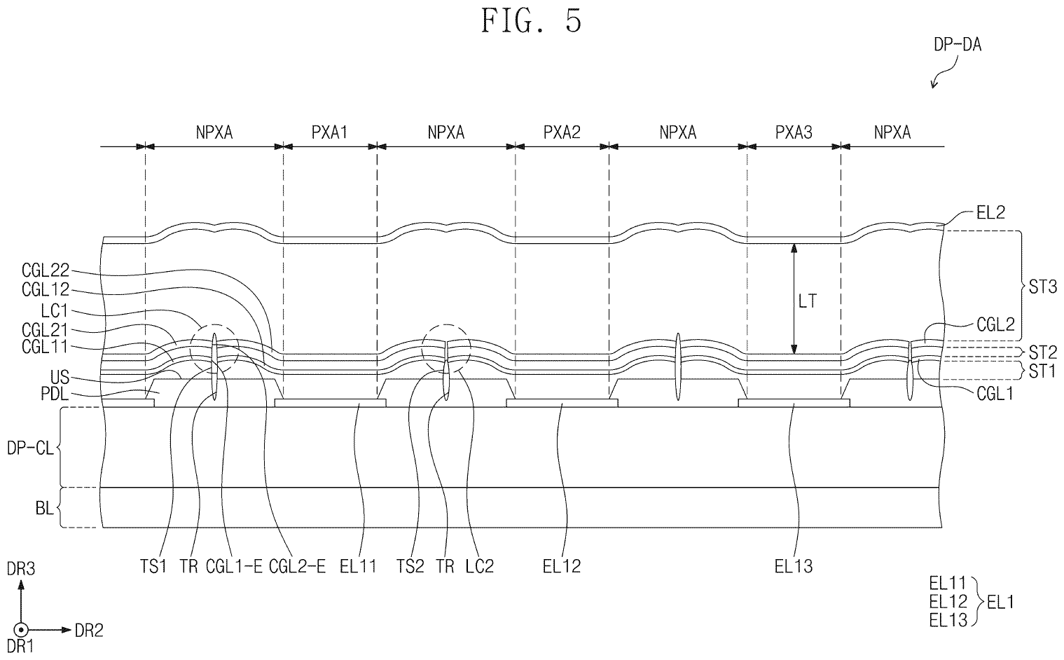

The second electrode EL2 may be arranged on the third light emitting stack ST3. For example, the second electrode EL2 may be arranged to face the first electrode EL1 with the light emitting stacks ST1, ST2, and ST3 interposed therebetween. The second electrode EL2 may have a single unitary form. For example, the second electrode EL2 may have a substantially continuous shape in an area overlapping a groove portion TR (see, e.g., FIG. 5) described in more detail later without being disconnected.

The second electrode EL2 may be a common electrode commonly arranged over the pixels.

The second electrode EL2 may be a cathode or an anode, however, the present disclosure is not limited thereto or thereby. As an example, if (e.g., when) the first electrode EL1 is the anode, the second electrode EL2 may be the cathode, and if (e.g., when) the first electrode EL1 is the cathode, the second electrode EL2 may be the anode.

The second electrode EL2 may be a transflective electrode or a transmissive electrode. In one or more embodiments in which the second electrode EL2 is the transmissive electrode, the second electrode EL2 may include a transparent metal oxide, e.g., indium tin oxide (ITO), indium zinc oxide (IZO), zinc oxide (ZnO), indium tin zinc oxide (ITZO), and/or the like.

In one or more embodiments in which the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, In, Zn, Sn, a compound thereof, and/or any suitable mixture thereof, e.g., AgMg, AgYb, or MgYb. In one or more embodiments, the second electrode EL2 may have a multi-layer structure of the reflective layer or a semi-transmissive layer, which is formed of the above-mentioned material, and a transparent conductive layer formed of indium tin oxide (ITO), indium zinc oxide (IZO), zinc oxide (ZnO), and/or indium tin zinc oxide (ITZO). As an example, the second electrode EL2 may include at least one selected from among the above-mentioned metal materials, a combination of two or more metal materials of (e.g., selected from among) the above-mentioned metal materials, or one or more oxides selected from among the above-mentioned metal materials.

In one or more embodiments, the second electrode EL2 may be connected to an auxiliary electrode. When the second electrode EL2 is connected to the auxiliary electrode, a resistance of the second electrode EL2 may be reduced.

The upper insulating layer TFL may be arranged on the display element layer DP-ED. The upper insulating layer TFL may include a capping layer CPL and an encapsulation layer TFE arranged on the capping layer CPL.

The capping layer CPL may be arranged on the second electrode EL2 and may cover the second electrode EL2. The capping layer CPL may include an organic material. The capping layer CPL may have a refractive index equal to or greater than about 1.6 in a wavelength range equal to or greater than about 550 nm and equal to or smaller than about 660 nm.

The encapsulation layer TFE may include a first inorganic encapsulation layer TIOL1, an organic encapsulation layer TOL arranged on the first inorganic encapsulation layer TIOL1, and a second inorganic encapsulation layer TIOL2 arranged on the organic encapsulation layer TOL. The first inorganic encapsulation layer TIOL1 and the second inorganic encapsulation layer TIOL2 may protect or substantially protect the display element layer DP-ED from moisture and oxygen, and the organic encapsulation layer TOL may protect or substantially protect the display element layer DP-ED from a foreign substance such as dust particles. However, the present disclosure is not limited thereto or thereby. According to one or more embodiments, the encapsulation layer TFE may further include an organic layer or an inorganic layer.

FIG. 5 is a cross-sectional view of the display panel in the display area DP-DA according to one or more embodiments of the present disclosure.

Hereinafter, an effect of blocking a lateral leakage current by the groove portion TR and a cross-section formed by the groove portion TR will be described with reference to FIG. 5. In FIG. 5, the same reference numerals denote the same elements in FIG. 4, and thus, detailed descriptions of the same elements may not be provided.

The groove portion TR may be defined in an upper surface US of the pixel definition layer PDL. The groove portion TR may be formed by recessing a portion of the upper surface US of the pixel definition layer PDL in a thickness direction.

FIG. 5 shows a structure in which one groove portion TR is defined in the pixel definition layer PDL in one non-pixel area NPXA; however, the present disclosure is not limited thereto or thereby. According to one or more embodiments, plural (e.g., two or more) groove portions TR may be defined in the pixel definition layer PDL in one non-pixel area NPXA.

The groove portion TR may be formed through a photoresist process. As an example, the photoresist process may be carried out after the pixel definition layer PDL is formed on the circuit element layer DP-CL and a mask is arranged on the pixel definition layer PDL to overlap the pixel definition layer PDL. The mask provided with an opening defined therethrough to correspond to the groove portion TR may be arranged on the pixel definition layer PDL, and the portion of the upper surface US of the pixel definition layer PDL may be etched by a dry etch process, thereby forming the groove portion TR. However, the process of forming the groove portion TR is not particularly limited as long as the portion of the upper surface US of the pixel definition layer PDL is etched.

FIG. 5 shows a structure in which the groove portion TR is formed at a center of the non-pixel area NPXA when viewed in cross-section as a representative example. However, the position of the groove portion TR should not be particularly limited as long as the groove portion TR is formed in the upper surface US of the pixel definition layer PDL.

For the convenience of explanation, FIG. 5 shows a structure in which an outer surface of the pixel definition layer PDL, which defines the groove portion TR, is curved when viewed in cross-section, however, this is merely an example. According to one or more embodiments, the outer surface of the pixel definition layer PDL, which defines the groove portion TR, is not limited to the curved surface as long as the portion of the upper surface US of the pixel definition layer PDL is recessed in the thickness direction.

Referring to FIG. 5, the base layer BL may include pixel areas PXA1, PXA2, and PXA3 and the non-pixel area NPXA.

The pixel areas PXA1, PXA2, and PXA3 may be distinguished from each other by the pixel definition layer PDL. The pixel areas PXA1, PXA2, and PXA3 may respectively correspond to the first electrodes EL1 exposed through the pixel openings OP (see, e.g., FIG. 4) without being covered by the pixel definition layer PDL.

The non-pixel area NPXA may correspond to an area between the pixel areas PXA1, PXA2, and PXA3 adjacent to each other and may correspond to the pixel definition layer PDL.

The pixel areas PXA1, PXA2, and PXA3 may include a first pixel area PXA1, a second pixel area PXA2, and a third pixel area PXA3. The first pixel area PXA1, the second pixel area PXA2, and the third pixel area PXA3 may be to emit lights having different wavelengths from each other. As an example, the first pixel area PXA1 may be to emit a first light in a blue wavelength, the second pixel area PXA2 may be to emit a second light in a green wavelength, and the third pixel area PXA3 may be to emit a third light in a red wavelength.

The first, second, and third pixel areas PXA1, PXA2, and PXA3 may have different sizes depending on wavelengths of the lights emitted therefrom. As an example, the first pixel area PXA1 emitting the first light in the blue wavelength may have the largest size among the first, second, and third pixel areas PXA1, PXA2, and PXA3, and the third pixel area PXA3 emitting the third light in the red wavelength may have the smallest size among the first, second, and third pixel areas PXA1, PXA2, and PXA3, however, the present disclosure is not limited thereto or thereby. According to one or more embodiments, the first, second, and third pixel areas PXA1, PXA2, and PXA3 may have the same size as each other.

After the groove portion TR is defined in the pixel definition layer PDL, the light emitting stacks ST1, ST2, and ST3, the charge generation layers CGL1 and CGL2, and the second electrode EL2 may be formed on the pixel definition layer PDL.

Because the curved surface is formed in the upper surface US of the pixel definition layer PDL by the groove portion TR, a deposition process of organic layers on the pixel definition layer PDL may be interfered with by the groove portion TR. As an example, the deposition process for the first light emitting stack ST1, the lower charge generation layer CGL1, the second light emitting stack ST2, and the upper charge generation layer CGL2 may be interfered with in the area overlapping the groove portion TR. Accordingly, pores TS1 and TS2 may be formed in the area overlapping the groove portion TR.

FIG. 5 shows the pores TS1 and TS2 including a first pore TS1 and a second pore TS2 having a length shorter than that of the first pore TS1 in the third direction DR3. In one or more embodiments, each of the first pore TS1 and the second pore TS2 may have an oval shape elongated in the third direction DR3, however, this is merely an example. Various shapes and types (kinds) of pores may be formed in the display panel DP (see, e.g., FIG. 3).

At least one pore may be formed in the first light emitting stack ST1 or the second light emitting stack ST2, and at least a portion of the areas where the pores TS1 and TS2 are defined may overlap the area where the (respective or corresponding) groove portion TR is formed if (e.g., when) viewed in a cross-section (e.g., in a cross-sectional view or overlap in a view on a plane defined by the DR3 direction).

For the convenience of explanation, FIG. 5 shows a first disconnection area LC1 and a second disconnection area LC2.

In the non-pixel area NPXA, the upper charge generation layer CGL2 may include a first upper portion CGL21 and a second upper portion CGL22, and the first upper portion CGL21 and the second upper portion CGL22 may be spaced and/or apart (e.g., spaced apart or separated) from each other with the area overlapping at least the portion of the groove portion TR interposed therebetween.

In the non-pixel area NPXA, the lower charge generation layer CGL1 may include a first lower portion CGL11 and a second lower portion CGL12, and the first lower portion CGL11 and the second lower portion CGL12 may be spaced and/or apart (e.g., spaced apart or separated) from each other with the area overlapping at least the portion of the groove portion TR interposed therebetween.

Referring to the first disconnection area LC1, at least a portion of the pore TS1 may be defined between the first lower portion CGL11 and the second lower portion CGL12. At least a portion of a side surface of each of the first lower portion CGL11 and the second lower portion CGL12 may be exposed through the pore TS1 (e.g., a side surface of each of the first lower portion CGL11 and the second lower portion CGL12 may define the pore TS1). At least a portion of the pore TS1 may be defined between the first upper portion CGL21 and the second upper portion CGL22. At least a portion of a side surface of each of the first upper portion CGL21 and the second upper portion CGL22 may be exposed through the pore TS1 (e.g., a side surface of each of the first upper portion CGL21 and the second upper portion CGL22 may define the pore TS1). FIG. 5 shows a structure in which a side surface CGL1-E of the first lower portion CGL11 and a side surface CGL2-E of the first upper portion CGL21 are exposed through the pore TS1 (e.g., a side surface CGL1-E of the first lower portion CGL11 and a side surface CGL2-E of the first upper portion CGL21 define the pore TS1).

Referring to the second disconnection area LC2, the pore TS2 may not be defined between the first lower portion CGL11 and the second lower portion CGL12. Accordingly, the side surface CGL1-E of the first lower portion CGL11 or the side surface CGL2-E of the first upper portion CGL21 may not be exposed through the pore TS2 (e.g., may not define the pore TS2). However, even though the side surface CGL1-E of the first lower portion CGL11 or the side surface CGL2-E of the first upper portion CGL21 are not exposed through the pore TS2, the first lower portion CGL11 and the second lower portion CGL12 may be spaced and/or apart (e.g., spaced apart or separated) from each other. In this case, an organic material utilized to form the third light emitting stack ST3 may be arranged at (in) at least a portion of an area between the first lower portion CGL11 and the second lower portion CGL12.

Different from the lower charge generation layer CGL1 and the upper charge generation layer CGL2, according to one or more embodiments, the second electrode EL2 may not be disconnected in the non-pixel area NPXA. Accordingly, the second electrode EL2 may be entirely arranged over each of the pixel area PXA and the non-pixel area NPXA. For example, the second electrode EL2 may have a substantially continuous and single unitary form and may serve as a common layer.

Because the lower charge generation layer CGL1, the upper charge generation layer CGL2, and a hole injection layer HIL (see, e.g., FIG. 6A) have conductivity, a current applied to one light emitting element ED (see, e.g., FIG. 4) may be leaked to another light emitting element ED (see, e.g., FIG. 4) adjacent to the one light emitting element ED. This leaked current may be defined as the lateral leakage current. In the case where the light is emitted from adjacent pixels due to the lateral leakage current, a color mixture may occur in the display panel DP (see, e.g., FIG. 3), and a luminescence of the display panel DP (see, e.g., FIG. 3) may be lowered.

According to one or more embodiments, the display panel DP (see, e.g., FIG. 3) may include the pixel definition layer PDL in which the groove portion TR is formed to disconnect the first light emitting stack ST1, the lower charge generation layer CGL11, the second light emitting stack ST2, and the upper charge generation layer CGL12, and the lateral leakage current may be prevented from flowing or the flow may be reduced. Therefore, the color mixture and luminance defects caused by the light emission of undesired pixels may be prevented or reduced.

As an example, the current applied to the first pixel area PXA1 may be prevented or reduced from being provided to the second pixel area PA2 adjacent thereto by not being able to leak (or by the leakage being reduced) through the first light emitting stack ST1, the lower charge generation layer CGL1, and the upper charge generation layer CGL2 in the non-pixel area NPXA.

In one or more embodiments, the third light emitting stack ST3 may be provided with sufficient thickness so that the second electrode EL2 is not affected by the groove portion TR. The third light emitting stack ST3 may be thicker than each of the first light emitting stack ST1 and the second light emitting stack ST2.

Therefore, the second electrode EL2 may be prevented or substantially prevented from being disconnected due to the groove portion TR. The thickness of the third light emitting stack ST3, which allows the second electrode EL2 not to be affected by the groove portion TR, will be described in more detail with reference to FIGS. 6A to 8C.

The first electrode EL1 may include a first-first electrode EL11 arranged in the first pixel area PXA1, a first-second electrode EL12 arranged in the second pixel area PXA2, and a first-third electrode EL13 arranged in the third pixel area PXA3. The thickness of each of the first-first electrode EL11, the first-second electrode EL12, and the first-third electrode EL13 may be adjusted to allow the light provided from each of the pixel areas PXA1, PXA2, and PXA3 to resonate. For example, optical lengths OL1, OL2, and OL3 (see, e.g., FIGS. 6A to 6C) of the light emitting element ED (see, e.g., FIG. 4) may be controlled or selected by adjusting the thickness of each of the first-first electrode EL11, the first-second electrode EL12, and the first-third electrode EL13.

FIGS. 6A to 6C are cross-sectional views of portions of the display panel according to one or more embodiments of the present disclosure.

A stack structure of components of the display panel DP (see, e.g., FIG. 3) in the first, second, and third pixel areas PXA1, PXA2, and PXA3 will be described in more detail with reference to FIGS. 6A to 6C.

The light emitting element ED (see, e.g., FIG. 4) may include a first light emitting element ED1 arranged in the first pixel area PXA1, a second light emitting element ED2 arranged in the second pixel area PXA2, and a third light emitting element ED3 arranged in the third pixel area PXA3.

The first light emitting element ED1 (see, e.g., FIG. 6A) may include the first-first electrode EL11, the first light emitting stack ST1, the lower charge generation layer CGL1, the second light emitting stack ST2, the upper charge generation layer CGL2, and the third light emitting stack ST3.

The second light emitting element ED2 (see, e.g., FIG. 6B) may include the first-second electrode EL12, the first light emitting stack ST1, the lower charge generation layer CGL1, the second light emitting stack ST2, the upper charge generation layer CGL2, and the third light emitting stack ST3.

The third light emitting element ED3 (see, e.g., FIG. 6C) may include the first-third electrode EL13, the first light emitting stack ST1, the lower charge generation layer CGL1, the second light emitting stack ST2, the upper charge generation layer CGL2, and the third light emitting stack ST3.

As shown in FIG. 6A, the first-first electrode EL11 may include a first conductive layer CDL1, a reflective layer RFL, and a second conductive layer CDL2, which are sequentially stacked. Each of the first conductive layer CDL1 and the second conductive layer CDL2 may include a transparent conductive oxide, and the reflective layer RFL may include a metal material.

As an example, each of the first conductive layer CDL1, the reflective layer RFL, and the second conductive layer CDL2 may have a three-layer structure of ITO/Ag/ITO; however, the present disclosure is not limited thereto or thereby. According to one or more embodiments, the first conductive layer CDL1 or the second conductive layer CDL2 may not be provided.

As shown in FIG. 6B, the first-second electrode EL12 may include the first conductive layer CDL1, the reflective layer RFL, a second optical auxiliary layer OA2, and the second conductive layer CDL2, which are sequentially stacked. As shown in FIG. 6C, the first-third electrode EL13 may include the first conductive layer CDL1, the reflective layer RFL, a third optical auxiliary layer OA3, and the second conductive layer CDL2, which are sequentially stacked.

As shown in FIG. 6A, the first light emitting element ED1 may include the first light emitting stack ST1, the lower charge generation layer CGL1, the second light emitting stack ST2, the upper charge generation layer CGL2, and the third light emitting stack ST3, which are sequentially stacked. For example, the first light emitting element ED1 may have the structure in which the first and second charge generation layers CGL1 and CGL2 are arranged between the first, second, and third light emitting stacks ST1, ST2, and ST3 adjacent to each other.

The first light emitting stack ST1 may include a hole transport region HTR, the first light emitting layer EML1 arranged on the hole transport region HTR, and a first intermediate electron transport region METR1 arranged on the first light emitting layer EML1.

The second light emitting stack ST2 may include a first intermediate hole transport region MHTR1, the second light emitting layer EML2 arranged on the first intermediate hole transport region MHTR1, and a second intermediate electron transport region METR2 arranged on the second light emitting layer EML2.

The third light emitting stack ST3 may include a second intermediate hole transport region MHTR2, the third light emitting layer EML3 arranged on the second intermediate hole transport region MHTR2 and an electron transport region ETR arranged on the third light emitting layer EML3.

The first light emitting element ED1 may be to emit a light in a direction from the first-first electrode EL11 to the second electrode EL2. The arrangement relationship between the components included in the first, second, and third light emitting stacks ST1, ST2, and ST3 should not be limited to the embodiments described above, and each of the first, second, and third light emitting stacks ST1, ST2, and ST3 may have an inverted element structure in which the electron transport region ETR is arranged under the light emitting layers EML1, EML2, and EML3 of the first, second, and third light emitting stacks ST1, ST2, and ST3 and the hole transport region HTR is arranged on the light emitting layers EML1, EML2, and EML3 of the first, second, and third light emitting stacks ST1, ST2, and ST3, when viewed in a direction to which the light travels.

The hole transport region HTR may transport holes provided from the first-first electrode EL11 to the first light emitting layer EML1. The first intermediate electron transport region METR1 may transport electrons generated by the first charge generation layer CGL1 to the first light emitting layer EML1.

The hole transport region HTR may include the hole injection layer HIL arranged on the first-first electrode EL11 and a hole transport layer HTL arranged on the hole injection layer HIL.

The hole injection layer HIL may be arranged on the second conductive layer CDL2. The hole injection layer HIL may be obtained by doping a base material with a p-dopant. The hole transport layer HTL may be in contact with a lower surface of the first light emitting layer EML1; however, the present disclosure is not limited thereto or thereby. According to one or more embodiments, the hole transport region HTR may further include a hole-side additional layer arranged on the hole transport layer HTL. In one or more embodiments, the hole-side additional layer may include at least one of a hole buffer layer, a light emitting auxiliary layer, and/or an electron blocking layer. The hole buffer layer may compensate for a resonance distance according to a wavelength of the light emitted from the light emitting layer and may improve a light emission efficiency. The electron blocking layer may prevent or substantially prevent the electrons from entering the hole transport region from the electron transport region.

When a voltage is applied, the charge generation layers CGL1 and CGL2 may form a complex through the oxidation-reduction reaction, and thus may generate the charges (electrons and holes). In one or more embodiments, the charge generation layers CGL1 and CGL2 may provide the generated charges to each of the first, second, and third light emitting stacks ST1, ST2, and ST3 adjacent thereto. The charge generation layers CGL1 and CGL2 may double the efficiency of current generated in the first, second, and third light emitting stacks ST1, ST2, and ST3 and may adjust a balance of the charges between the first, second, and third light emitting stacks ST1, ST2, and ST3 adjacent to each other.

In one or more embodiments, the first charge generation layer CGL1 may have a layer structure in which a first n-type or kind charge generation layer and a first p-type or kind charge generation layer are bonded to each other. The second charge generation layer CGL2 may have a layer structure in which a second n-type or kind charge generation layer and a second p-type or kind charge generation layer are bonded to each other.

The n-type or kind charge generation layer may be the charge generation layer that provides the electrons to the light emitting stacks adjacent thereto. The n-type or kind charge generation layer may be obtained by doping a base material with an n-dopant. The p-type or kind charge generation layer may provide the holes to the light emitting stacks adjacent thereto.

in one or more embodiments, a buffer layer may be further arranged between the n-type or kind charge generation layer and the p-type or kind charge generation layer.

Each of the charge generation layers CGL1 and CGL2 may include the n-type or kind aryl amine-based material or the p-type or kind metal oxide. Each of the charge generation layers CGL1 and CGL2 may include a charge-generating compound containing an aryl amine-based organic compound, a metal, an oxide of a metal, a carbide, a fluoride, and/or any suitable mixture thereof.

As an example, the aryl amine-based organic compound may be α-NPD, 2-TNATA, TDATA, MTDATA, spiro-TAD, or spiro-NPB. For example, the metal may be cesium (Cs), molybdenum (Mo), vanadium (V), titanium (Ti), tungsten (W), barium (Ba), or lithium (Li). Also, for example, the oxide of the metal, the carbide, and/or the fluoride may be Re₂O₇, MoO₃, V₂O₅, WO₃, TiO₂, Cs₂CO₃, BaF, LiF, and/or CsF.

The first intermediate electron transport region METR1 may include a first intermediate electron transport layer arranged on the first light emitting layer EML1. The first intermediate electron transport layer may be arranged between the first light emitting layer EML1 and the first charge generation layer CGL1 and may be in contact with the first light emitting layer EML1.

The first intermediate electron transport region METR1 may further include a first intermediate electron injection layer arranged between the first intermediate electron transport layer and the first charge generation layer CGL1. The first intermediate electron transport region may further include a first intermediate electron-side additional layer arranged between the first intermediate electron transport layer and the first light emitting layer EML1. The first intermediate electron-side additional layer may include at least one of an electron buffer layer and/or a hole blocking layer.

The first intermediate hole transport region MHTR1 may transport holes generated by the first charge generation layer CGL1 to the second light emitting layer EML2. The second intermediate electron transport region METR2 may transport electrons provided from the second charge generation layer CGL2 to the second light emitting layer EML2.

The first intermediate hole transport region MHTR1 may include a first intermediate hole injection layer arranged on the first charge generation layer CGL1 and a first intermediate hole transport layer arranged on the first intermediate hole injection layer. The first intermediate hole transport layer may be in contact with a lower surface of the second light emitting layer EML2.

The first intermediate hole transport region MHTR1 may further include a first intermediate hole-side additional layer arranged on the first intermediate hole transport layer. The first intermediate hole-side additional layer may include at least one of a hole buffer layer, a light emitting auxiliary layer, and/or an electron blocking layer.

The second intermediate electron transport region METR2 may include a second intermediate electron transport layer arranged on the second light emitting layer EML2. The second intermediate electron transport layer may be arranged between the second light emitting layer EML2 and the second charge generation layer CGL2 and may be in contact with the second light emitting layer EML2. The second intermediate electron transport region METR2 may further include a second intermediate electron injection layer arranged between the second intermediate electron transport layer and the second charge generation layer CGL2. The second intermediate electron transport region METR2 may further include a second intermediate electron-side additional layer arranged between the second intermediate electron transport layer and the second light emitting layer EML2. The second intermediate electron-side additional layer may include at least one of an electron buffer layer and/or a hole blocking layer.

The second intermediate hole transport region MHTR2 may transport holes generated by the second charge generation layer CGL2 to the third light emitting layer EML3. The electron transport region ETR may transport electrons provided from a third charge generation layer to the third light emitting layer EML3.

The second intermediate hole transport region MHTR2 may include a second intermediate hole injection layer arranged on the second charge generation layer CGL2 and a second intermediate hole transport layer arranged on the second intermediate hole injection layer. The second intermediate hole transport layer may be in contact with a lower surface of the third light emitting layer EML3; however, the present disclosure is not limited thereto or thereby. According to one or more embodiments, the second intermediate hole transport region MHTR2 may further include a second intermediate hole-side additional layer arranged on the second intermediate hole transport layer. The second intermediate hole-side additional layer may include at least one of a hole buffer layer, a light emitting auxiliary layer, and/or an electron blocking layer.

The electron transport region ETR may include an electron transport layer ETL arranged on the third light emitting layer EML3 and an electron injection layer EIL arranged on the electron transport layer ETL. The electron transport layer ETL may be in contact with the third light emitting layer EML3; however, the present disclosure should not be limited thereto or thereby. According to one or more embodiments, the electron transport region ETR may further include an electron-side additional layer arranged between the electron transport layer ETL and the third light emitting layer EML3. The electron-side additional layer may include at least one of an electron buffer layer and/or a hole blocking layer.

The first, second, and third light emitting layers EML1, EML2, and EML3 may be to emit lights having specific wavelengths different from each other. According to one or more embodiments, the first light emitting layer EML1 may be to emit a light having a first wavelength, the second light emitting layer EML2 may be to emit a light having a second wavelength, and the third light emitting layer EML3 may be to emit a light having a third wavelength.

The light having the first wavelength may be a light in a blue wavelength range. The light having the first wavelength may be the light in a wavelength range equal to or greater than about 410 nm and equal to or smaller than about 480 nm. The light having the second wavelength may be a light in a green wavelength range. The light having the second wavelength may be the light in a wavelength range equal to or greater than about 500 nm and equal to or smaller than about 600 nm. The light having the third wavelength may be a light in a red wavelength range. The light having the third wavelength may be the light in a wavelength range equal to or greater than about 620 nm and equal to or smaller than about 700 nm.

Each of the first, second, and third light emitting layers EML1, EML2, and EML3 may include a host material and a blue light emitting dopant. The dopant included in each of the first, second, and third light emitting layers EML1, EML2, and EML3 may be a blue fluorescent dopant. The first, second, and third light emitting layers EML1, EML2, and EML3 may include substantially the same host material and the same dopant.

The first light emitting element ED1 may include the first, second, and third light emitting stacks ST1, ST2, and ST3 emitting the lights in different wavelength ranges and thus may be to emit a white color.

As shown in FIG. 6A, a first color filter CF1 may be arranged on the upper insulating layer TFL. The first color filter CF1 may overlap the first pixel area PXA1 and may be to transmit a first color light. Accordingly, only the first color light among the lights forming the white color light emitted from the first light emitting element ED1 may be transmitted through the first color filter CF1.

As shown in FIG. 6B, a second color filter CF2 may be arranged on the upper insulating layer TFL. The second color filter CF2 may overlap the second pixel area PXA2 and may be to transmit a second color light. Accordingly, only the second color light among the lights forming the white color light emitted from the second light emitting element ED2 may be transmitted through the second color filter CF2.

As shown in FIG. 6C, a third color filter CF3 may be arranged on the upper insulating layer TFL. The third color filter CF3 may overlap the third pixel area PXA3 and may be to transmit a third color light. Accordingly, only the third color light among the lights forming the white color light emitted from the third light emitting element ED3 may be transmitted through the third color filter CF3.

In embodiments of the present disclosure, the optical length OL may be defined as a distance between an upper surface of the reflective layer RFL and a lower surface of the second electrode EL2.

According to one or more embodiments, the optical length OL1 in the first pixel area PXA1 may be an (n+2)th-order resonance thickness of the blue light, the optical length OL2 in the second pixel area PXA2 may be an (n+1)th-order resonance thickness of the green light, and the optical length OL3 in the third pixel area PXA3 may be an nth-order resonance thickness of the red light. In this case, n may be an integer equal to or greater than 1.

In embodiments of the present disclosure, a distance from the first light emitting layer EML1 to the reflective layer RFL in the first pixel area PXA1 may be defined as a first color distance CD1, a distance from the second light emitting layer EML2 to the reflective layer RFL in the second pixel area PXA2 may be defined as a second color distance CD2, and a distance from the third light emitting layer EML3 to the reflective layer RFL in the third pixel area PXA3 may be defined as a third color distance CD3.

The first electrode EL1 (see, e.g., FIG. 4) may include an optical auxiliary layer arranged at at least a portion between the reflective layer RFL and the second conductive layer CDL2. The optical auxiliary layer may include the second optical auxiliary layer OA2 (see, e.g., FIG. 6B) and the third optical auxiliary layer OA3 (see, e.g., FIG. 6C).

According to the light emitting elements ED1, ED2, and ED3 shown in FIGS. 6A to 6C, the optical auxiliary layer may not be arranged between the reflective layer RFL and the second conductive layer CDL2 in the first pixel area PXA1, the second optical auxiliary layer OA2 may be arranged between the reflective layer RFL and the second conductive layer CDL2 in the second pixel area PXA2, and the third optical auxiliary layer OA3 may be arranged between the reflective layer RFL and the second conductive layer CDL2 in the third pixel area PXA3.

The optical auxiliary layer may finely adjust the optical lengths OL1, OL2, and OL3 to allow the lights respectively emitted from the first, second, and third pixel areas PXA1, PXA2, and PXA3 to resonate. For example, the optical auxiliary layer may adjust the optical lengths OL1, OL2, and OL3 in the first, second, and third pixel areas PXA1, PXA2, and PXA3 such that the lights emitted from the first, second, and third light emitting layers EML1, EML2, and EML3 and the lights reflected by the first electrode EL1 may constructively interfere with each other.

Referring to FIGS. 6A to 6C, the second optical auxiliary layer OA2 may have a thickness equal to or greater than about 400 angstrom (Å) and equal to or smaller than about 500 Å in the second pixel area PXA2 of the light emitting element ED (see, e.g., FIG. 4), and the third optical auxiliary layer OA3 may have a thickness equal to or greater than about 150 Å and equal to or smaller than about 250 Å in the third pixel area PXA3.

Accordingly, the first color distance CD1 may be equal to or greater than about 1350 Å and equal to or smaller than about 1550 Å in the first pixel area PXA1, the second color distance CD2 may be equal to or greater than about 2200 Å and equal to or smaller than about 2400 Å in the second pixel area PXA2, and the third color distance CD3 may be equal to or greater than about 7350 Å and equal to or smaller than about 7550 Å in the third pixel area PXA3.

In the light emitting elements ED1, ED2, and ED3 shown in FIGS. 6A to 6C, n may be 5. For example, the optical length OL1 in the first pixel area PXA1 may be a seventh-order resonance thickness of the blue light, the optical length OL2 in the second pixel area PXA2 may be a sixth-order resonance thickness of the green light, and the optical length OL3 in the third pixel area PXA3 may be a fifth-order resonance thickness of the red light.

As the optical lengths OL1, OL2, and OL3 are improved or optimized to allow the lights respectively emitted from the first, second, and third pixel areas PXA1, PXA2, and PXA3 to resonate, an intensity of the lights respectively emitted from the first, second, and third pixel areas PXA1, PXA2, and PXA3 may increase.

Referring to FIG. 5, a distance from an upper surface of the upper charge generation layer CGL2 to the second electrode EL2 may be referred to as a connection thickness LT in the following descriptions. As described above, if (e.g., when) the upper charge generation layer CGL2 and the second electrode EL2 are not sufficiently spaced and/or apart (e.g., spaced apart or separated) from each other, the second electrode EL2 may be disconnected due to the groove portion TR in the area overlapping the area in which the groove portion TR is defined. In embodiments of the present disclosure, the expression “The upper charge generation layer CGL2 and the second electrode EL2 are sufficiently spaced and/or apart (e.g., spaced apart or separated) from each other” means that the upper charge generation layer CGL2 and the second electrode EL2 are spaced and/or apart (e.g., spaced apart or separated) from each other to an extent that allows the second electrode EL2 not to be disconnected in the area overlapping the area where the groove portion TR is defined. As an example, if (e.g., when) the connection thickness LT is equal to or greater than about 3500 Å, the upper charge generation layer CGL2 and the second electrode EL2 may be sufficiently spaced and/or apart (e.g., spaced apart or separated) from each other.

Referring to FIGS. 5 and 6A to 6C, the thickness of the second intermediate hole transport region MHTR2 may be adjusted to secure the connection thickness LT that allows the upper charge generation layer CGL2 to be sufficiently spaced and/or apart (e.g., spaced apart or separated) from the second electrode EL2. As an example, the thickness of the second intermediate hole transport layer included in the second intermediate hole transport region MHTR2 may be adjusted to secure the connection thickness LT that allows the upper charge generation layer CGL2 to be sufficiently spaced and/or apart (e.g., spaced apart or separated) from the second electrode EL2.

The connection thickness LT may be equal to or greater than about 4350 Å and equal to or smaller than about 4450 Å. Thus, the upper charge generation layer CGL2 may be sufficiently spaced and/or apart (e.g., spaced apart or separated) from the second electrode EL2. Accordingly, the charge generation layers CGL1 and CGL2 and the hole injection layer HIL may be disconnected in the non-pixel area NPXA (see, e.g., FIG. 5) to prevent or reduce the occurrence of the lateral leakage current, and the second electrode EL2 may be entirely arranged over (e.g., substantially continuous across) each of the pixel area PXA (see, e.g., FIG. 4) and the non-pixel area NPXA (see, e.g., FIG. 4). Consequently, color mixing between the pixels adjacent to each other may be prevented or reduced, and a function of the second electrode EL2 may be prevented or substantially prevented from being lost.

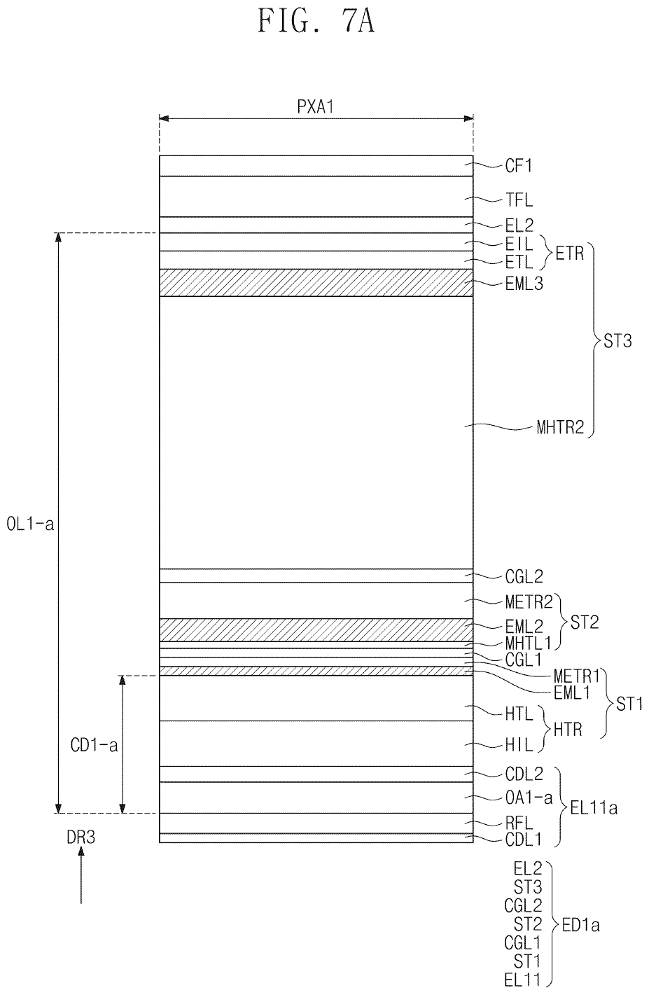

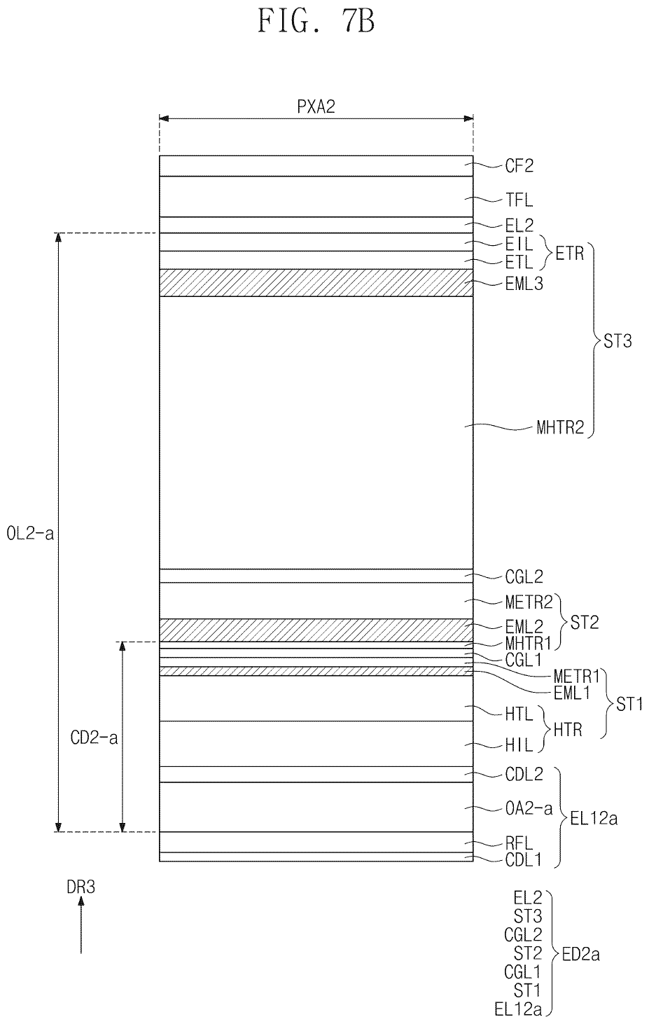

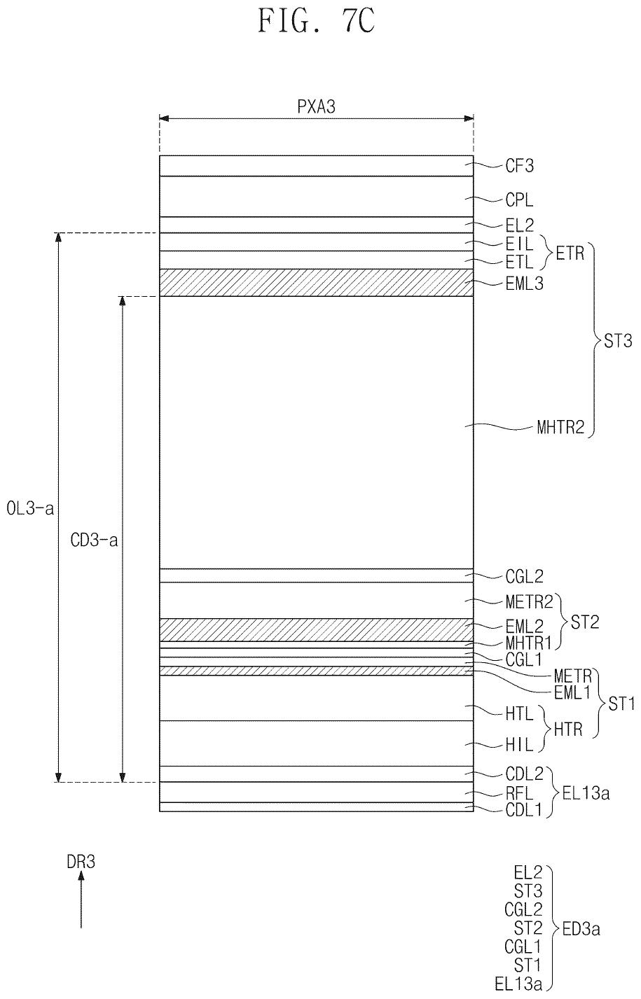

FIGS. 7A to 7C are cross-sectional views of portions of a display panel according to one or more embodiments of the present disclosure.

A stack structure of components of the display panel in first, second, and third pixel areas PXA1, PXA2, and PXA3 will be described in more detail with reference to FIGS. 7A to 7C. In FIGS. 7A to 7C, the same/similar reference numerals denote the same/similar elements in FIGS. 6A to 6C, and thus, detailed descriptions of the same/similar elements may not be provided.

A light emitting element may include a first light emitting element ED1a arranged in the first pixel area PXA1, a second light emitting element ED2a arranged in the second pixel area PXA2, and a third light emitting element ED3a arranged in the third pixel area PXA3.

Components included in the first, second, and third light emitting elements ED1a, ED2a, and ED3a shown in FIGS. 7A to 7C may respectively correspond to the components included in the first, second, and third light emitting elements ED1, ED2, and ED3 shown in FIGS. 6A to 6C.

Different from the display panel shown in FIGS. 6A to 6C, a first-first electrode EL11a included in the first light emitting element ED1a may include a first optical auxiliary layer OA1-a arranged between a reflective layer RFL and a second conductive layer CDL2. A first-second electrode EL12a included in the second light emitting element ED2a may include a second optical auxiliary layer OA2-a arranged between the reflective layer RFL and the second conductive layer CDL2. However, a first-third electrode EL13a included in the third light emitting element ED3a may not include (e.g., may exclude) an optical auxiliary layer between the reflective layer RFL and the second conductive layer CDL2.

Referring to FIGS. 7A to 7C, the first optical auxiliary layer OA1-a included in the first-first electrode EL11a of the first light emitting element ED1a may have a thickness equal to or greater than about 200 Å and equal to or smaller than about 400 Å, and the second optical auxiliary layer OA2-a included in the first-second electrode EL12a of the second light emitting element ED2a may have a thickness equal to or greater than about 500 Å and equal to or smaller than about 700 Å.

Accordingly, a first color distance CD1-a may be within a range equal to or greater than about 1350 Å and equal to or smaller than about 1550 Å in the first pixel area PXA1, a second color distance CD2-a may be within a range equal to or greater than about 2200 Å and equal to or smaller than about 2400 Å in the second pixel area PXA2, and a third color distance CD3-a may be within a range equal to or greater than about 5650 Å and equal to or smaller than about 5850 Å in the third pixel area PXA3.

In the first, second, and third light emitting elements ED1a, ED2a, and ED3a shown in FIGS. 7A to 7C, n may be 4. For example, an optical length OL1-a may be a sixth-order resonance thickness of a blue light in the first pixel area PXA1, an optical length OL2-a may be a fifth-order resonance thickness of a green light in the second pixel area PXA2, and an optical length OL3-a may be a fourth-order resonance thickness in the third pixel area PXA3.

As the optical lengths OL1-a, OL2-a, and OL3-a are improved or optimized to allow the lights respectively emitted from the first, second, and third pixel areas PXA1, PXA2, and PXA3 to resonate, an intensity of the lights respectively emitted from the first, second, and third pixel areas PXA1, PXA2, and PXA3 may increase.

According to one or more embodiments, a thickness of a second intermediate hole transport layer may be adjusted to allow a connection thickness LT (see, e.g., FIG. 5) included in the first to third light emitting elements ED1a to ED3a to be equal to or greater than 3850 Å and equal to or smaller than 4150 Å. Accordingly, an upper charge generation layer CGL2 may be sufficiently spaced and/or apart (e.g., spaced apart or separated) from a second electrode EL2. Therefore, the charge generation layers CGL1 and CGL2 and a hole injection layer HIL may be disconnected in a non-pixel area NPXA (see, e.g., FIG. 5) to prevent or reduce the occurrence of the lateral leakage current, and the second electrode EL2 may be entirely arranged over (e.g., substantially continuous across) each of a pixel area PXA (see, e.g., FIG. 4) and the non-pixel area NPXA (see, e.g., FIG. 4). Accordingly, color mixing between pixels adjacent to each other in the display panel DP (see, e.g., FIG. 3) may be prevented or reduced, and a function of the second electrode EL2 may be prevented or substantially prevented from being lost.

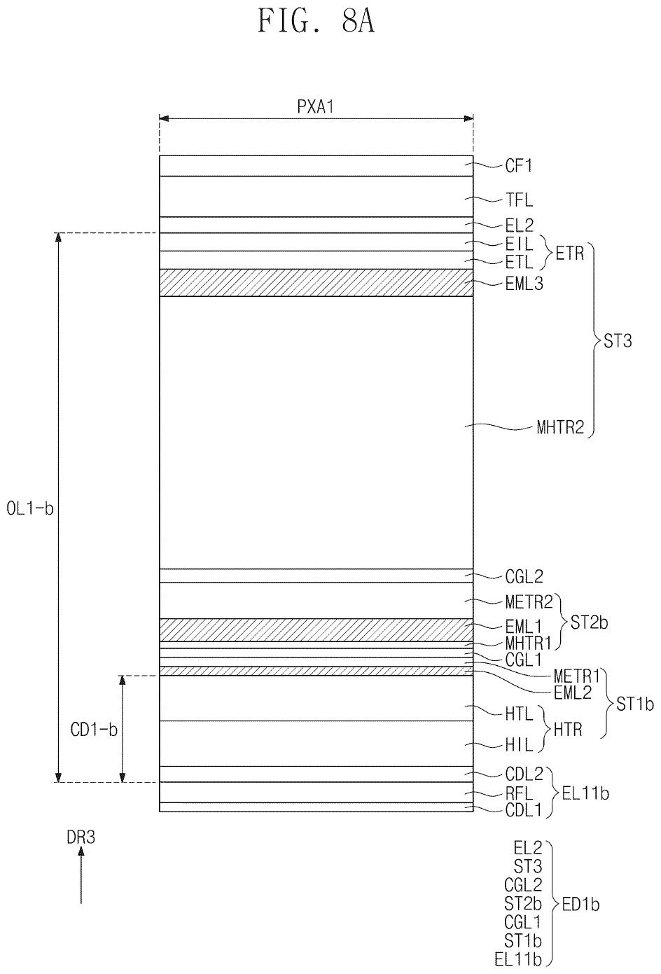

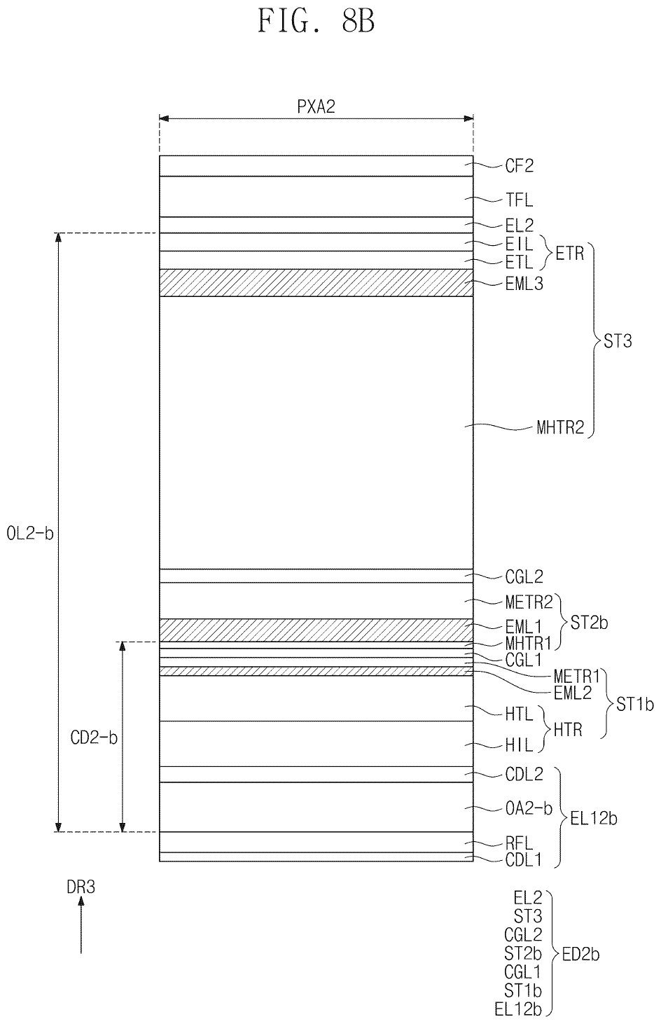

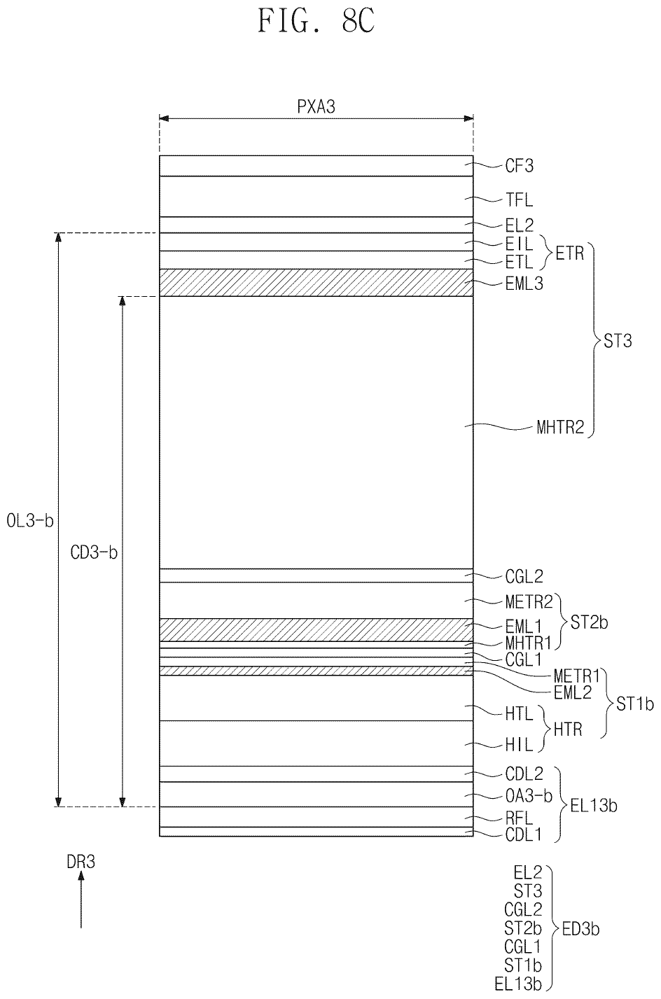

FIGS. 8A to 8C are cross-sectional views of portions of a display panel according to one or more embodiments of the present disclosure.

A stack structure of components of the display panel in first, second, and third pixel areas PXA1, PXA2, and PXA3 will be described in more detail with reference to FIGS. 8A to 8C. In FIGS. 8A to 8C, the same/similar reference numerals denote the same/similar elements in FIGS. 6A to 6C, and thus, detailed descriptions of the same/similar elements may not be provided.

A light emitting element may include a first light emitting element ED1b arranged in the first pixel area PXA1, a second light emitting element ED2b arranged in the second pixel area PXA2, and a third light emitting element ED3b arranged in the third pixel area PXA3.

Referring to FIGS. 8A to 8C, a first light emitting stack ST1b may include a hole transport region HTR, a second light emitting layer EML2 arranged on the hole transport region HTR, and a first intermediate electron transport region METR1 arranged on the second light emitting layer EML2. In one or more embodiments, a second light emitting stack ST2b may include a first intermediate hole transport region MHTR1, a first light emitting layer EML1 arranged on the first intermediate hole transport region MHTR1, and a second intermediate electron transport region METR2 arranged on the first light emitting layer EML1. Accordingly, the first, second, and third light emitting layers EML1, EML2, and EML3 may be arranged in the order of the second light emitting layer EML2, the first light emitting layer EML1, and the third light emitting layer EML3 with respect to the third direction DR3.

A first-first electrode EL11b included in the first light emitting element ED1b may not include (e.g., may exclude) an optical auxiliary layer. A second optical auxiliary layer OA2-b included in a first-second electrode EL12b of the second light emitting element ED2b may have a thickness equal to or greater than about 400 Å and equal to or smaller than about 600 Å. A third optical auxiliary layer OA3-b included in a first-third electrode EL13b of the third light emitting element ED3b may have a thickness equal to or greater than about 200 Å and equal to or smaller than about 400 Å.

Accordingly, a first color distance CD1-b may be within a range equal to or greater than about 2660 Å and equal to or smaller than about 2860 Å in the first pixel area PXA1, a second color distance CD2-b may be within a range equal to or greater than about 1860 Å and equal to or smaller than about 2060 Å in the second pixel area PXA2, and a third color distance CD3-b may be within a range equal to or greater than about 7400 Å and equal to or smaller than about 7600 Å in the third pixel area PXA3.

In the first, second, and third light emitting elements ED1b, ED2b, and ED3b shown in FIGS. 8A to 8C, n may be 5. For example, an optical length OL1-b may be a seventh-order resonance thickness of a blue light in the first pixel area PXA1, an optical length OL2-b may be a sixth-order resonance thickness of a green light in the second pixel area PXA2, and an optical length OL3-b may be a fifth-order resonance thickness of a red light in the third pixel area PXA3.

As the optical lengths OL1-b, OL2-b, and OL3-b are improved or optimized to allow the lights respectively emitted from the first, second, and third pixel areas PXA1, PXA2, and PXA3 to resonate, an intensity of the lights respectively emitted from the first, second, and third pixel areas PXA1, PXA2, and PXA3 may increase.

According to one or more embodiments, a thickness of a second intermediate hole transport layer may be adjusted to allow a connection thickness LT (see, e.g., FIG. 5) included in the first to third light emitting elements ED1b to ED3b to be equal to or greater than about 4350 Å and equal to or smaller than about 4450 Å. Accordingly, an upper charge generation layer CGL2 may be sufficiently spaced and/or apart (e.g., spaced apart or separated) from a second electrode EL2. Therefore, the charge generation layers CGL1 and CGL2 and a hole injection layer HIL may be disconnected in a non-pixel area NPXA (see, e.g., FIG. 5) to prevent or reduce the occurrence of the lateral leakage current, and the second electrode EL2 may be entirely arranged over (e.g., substantially continuous across) each of a pixel area PXA (see, e.g., FIG. 4) and the non-pixel area NPXA (see, e.g., FIG. 4). Accordingly, color mixing between the pixels adjacent to each other in the display panel DP (see, e.g., FIG. 3) may be prevented or reduced, and a function of the second electrode EL2 may be prevented or substantially prevented from being lost.

Hereinafter, the light emitting element according to embodiments of the present disclosure will be described in more detail with reference to Examples and a Comparative Example. Examples shown below are to aid understanding of the present disclosure, and the scope of the present disclosure is not limited thereto or thereby.

### Characteristics Evaluation of Examples 1 to 3 and Comparative Example

The light emitting element of Example 1 corresponds to the first to third light emitting elements ED1 to ED3 described with reference to FIGS. 6A to 6C. The light emitting element of Example 2 corresponds to the first to third light emitting elements ED1a to ED3a described with reference to FIGS. 7A to 7C. The light emitting element of Example 3 corresponds to the first to third light emitting elements ED1b to ED3b described with reference to FIGS. 8A to 8C. In these examples, the first light emitting layer corresponds to a blue light emitting layer emitting the blue light, the second light emitting layer corresponds to a green light emitting layer emitting the green light, and the third light emitting layer corresponds to a red light emitting layer emitting the red light as described with reference to FIGS. 6A to 6C, 7A to 7C, and 8A to 8C. The light emitting element of the Comparative Example includes a red light emitting layer, a blue light emitting layer, and a green light emitting layer that are sequentially stacked in the third direction and corresponds to a light emitting element where the blue light, the green light, and the red light do not have sequential resonance thicknesses.

The evaluation results of Examples 1 to 3 and the Comparative Example are shown in Tables 1 to 3. Tables 1, 2, and 3 are evaluation tables showing a light efficiency of the red light, the green light, and the blue light, respectively. In Tables 1, 2, and 3, “x coordinate” and “y coordinate” correspond to optimal or suitable color coordinates to emit an optimal or suitable color, “light efficiency” is an energy of emitted light with respect to an electrical energy utilized, and “efficiency” indicates a relative efficiency when a light efficiency of the light emitting element of the Comparative Example is set to 100%.

TABLE 1

| | Driving | | | Light | |
|---|---|---|---|---|---|
| | voltage | X | Y | efficiency | Efficiency |
| Structure | (V) | coordinate | coordinate | (cd/A) | (%) |
| Comparative | 11.6 | 0.675 | 0.324 | 25.9 | 100% |
| Example | | | | | |
| Example 1 | 12.8 | 0.673 | 0.327 | 55.6 | 215% |
| Example 2 | 11.3 | 0.682 | 0.317 | 56.0 | 216% |
| Example 3 | 13.2 | 0.672 | 0.327 | 44.8 | 173% |

TABLE 2

| | | | | | |
|---|---|---|---|---|---|
| | Driving | | | Light | |
| | voltage | X | Y | efficiency | Efficiency |
| Structure | (V) | coordinate | coordinate | (cd/A) | (%) |

| | | | | |
|---|---|---|---|---|
| Comparative | | | | — |
| Example | | | | |
| Example 1 | | | | 180% |
| Example 2 | | | | 187% |
| Example 3 | 12.9 | 0.247 | 71.0 | 181% |

TABLE 3

| | Driving | | | Light | |
|---|---|---|---|---|---|
| | voltage | X | Y | efficiency | Efficiency |
| Structure | (V) | coordinate | coordinate | (cd/A /y) | (%) |
| Comparative | | | 0.040 | | — |
| Example | | | | | |
| Example 1 | | | 0.069 | | 60% |
| Example 2 | | 0.149 | 0.051 | | 79% |
| Example 3 | 12.9 | 0.143 | 0.057 | 69.6 | 82% |

Referring to results of Tables 1 to 3, the light emitting elements of the Examples each have a similar level of driving voltage compared to the light emitting element of the Comparative Example. In addition, the light emitting elements of Examples each have a relatively high light efficiency compared to the light emitting element of the Comparative Example.

Table 4 is an evaluation table showing the light efficiency with respect to the white color in the light emitting elements of the Comparative Example and Examples.

TABLE 4

| | Comparative | | | |
|---|---|---|---|---|
| Structure | Example | Example 1 | Example 2 | Example 3 |
| W efficiency | 23.3 | | | 29.4 |
| Efficiency (%) | — | 108% | 129% | 126% |

Referring to the results of Table 4, the light emitting elements of the Examples each have the light efficiency higher than that of the light emitting element of the Comparative Example. The efficiency of emitting the white light may be improved or optimized in the light emitting elements of Examples.

In present disclosure, “not including a or any ‘component’” “excluding a or any ‘component’”, “‘component’-free”, and/or the like refers to that the “component” not being added, selected or utilized as a component in the composition/structure, but the “component” of less than a suitable amount may still be included due to other impurities and/or external factors.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A display device comprising:
a base layer comprising a first pixel area, a second pixel area adjacent to the first pixel area, and a third pixel area adjacent to the second pixel area;
a first electrode on the base layer and comprising a reflective layer;
a first light emitting layer on the first electrode and to generate a blue light;
a second light emitting layer on the first electrode and to generate a green light;
a third light emitting layer on the first light emitting layer and the second light emitting layer and to generate a red light; and
a second electrode on the third light emitting layer, and
wherein a distance from a lower surface of the second electrode to an upper surface of the reflective layer is defined as an optical length, the optical length in the first pixel area is an (n+2)th-order resonance thickness of the blue light, the optical length in the second pixel area is an (n+1)th-order resonance thickness of the green light, the optical length in the third pixel area is an nth-order resonance thickness of the red light, and n is an integer equal to or greater than 1.

2. The display device of claim 1, wherein at least one of the first electrode of the first pixel area, the first electrode of the second pixel area or the first electrode of the third pixel area further comprises:
a first conductive layer under the reflective layer; and
a second conductive layer on the reflective layer, and each of the first conductive layer and the second conductive layer comprise a transparent conductive oxide.

3. The display device of claim 2, wherein
the second light emitting layer is on the first light emitting layer,
a distance from the first light emitting layer to the reflective layer in the first pixel area is equal to or greater than about 1350 angstroms and equal to or smaller than about 1550 angstroms, and
a distance from the second light emitting layer to the reflective layer in the second pixel area is equal to or greater than about 2200 angstroms and equal to or smaller than about 2400 angstroms.

4. The display device of claim 2, wherein the n is 5, and a distance from the third light emitting layer to the reflective layer in the third pixel area is equal to or greater than about 7350 angstroms and equal to or smaller than about 7550 angstroms.

5. The display device of claim 2, wherein the n is 4, and a distance from the third light emitting layer to the reflective layer in the third pixel area is equal to or greater than about 5650 angstroms and equal to or smaller than about 5850 angstroms.

6. The display device of claim 2, wherein the first light emitting layer is on the second light emitting layer, the n is 5, a distance from the first light emitting layer to the reflective layer in the first pixel area is equal to or greater than about 2660 angstroms and equal to or smaller than about 2860 angstroms, a distance from the second light emitting layer to the reflective layer in the second pixel area is equal to or greater than about 1860 angstroms and equal to or smaller than about 2060 angstroms, and a distance from the third light emitting layer to the reflective layer in the third pixel area is equal to or greater than about 7400 angstroms and equal to or smaller than about 7600 angstroms.

7. A display device comprising:
a base layer comprising a pixel area and a non-pixel area around the pixel area;
a circuit element layer on the base layer; and
a display element layer on the circuit element layer and comprising a pixel definition layer in which a groove portion is defined, and a light emitting element, wherein at least a portion of the light emitting element is on the pixel definition layer, the light emitting element comprising:
a first electrode;
a first light emitting stack on the first electrode;
a second light emitting stack on the first electrode;
a lower charge generation layer between the first light emitting stack and the second light emitting stack;
a third light emitting stack on the first light emitting stack and the second light emitting stack;
an upper charge generation layer between the second light emitting stack and the third light emitting stack; and
a second electrode on the upper charge generation layer, wherein the second electrode and the second charge generation layer are spaced from each other with the third light emitting stack interposed therebetween in an area overlapping the groove portion, and the second electrode is substantially continuous arranged across the pixel area and the non-pixel area.

8. The display device of claim 7, wherein the third light emitting stack has a thickness greater than a thickness of the first light emitting stack and also has the thickness greater than a thickness of the second light emitting stack.

9. The display device of claim 7, wherein:
the upper charge generation layer comprises a first upper portion and a second upper portion in the non-pixel area, the first upper portion and the second upper portion are spaced from each other with an area where at least a portion of the first upper portion or the second upper portion overlap the groove portion interposed therebetween, and
the lower charge generation layer comprises a first lower portion and a second lower portion in the non-pixel area, and the first lower portion and the second lower portion are spaced from each other with an area where at least a portion of the first lower portion or the second lower portion overlap the groove portion interposed therebetween.

10. The display device of claim 9, wherein at least one pore is defined in the first light emitting stack or the second light emitting stack, and an area where the pore is defined at least partially overlaps the area where the groove portion is defined.

11. The display device of claim 10, wherein at least a portion of the pore is defined between the first lower portion and the second lower portion.

12. The display device of claim 10, wherein at least a portion of a side surface of each of the first lower portion and the second lower portion is exposed through the pore.

13. The display device of claim 7, wherein the pixel area comprises a first pixel area, a second pixel area adjacent to the first pixel area, and a third pixel area adjacent to the second pixel area.

14. The display device of claim 13, wherein the first electrode comprises:
a first conductive layer;
a reflective layer on the first conductive layer;
a second conductive layer on the reflective layer; and
an optical auxiliary layer at at least a portion between the reflective layer and the second conductive layer, and the optical auxiliary layer comprises:
a second optical auxiliary layer overlapping the second pixel area; and
a third optical auxiliary layer overlapping the third pixel area.

15. The display device of claim 14, wherein the second light emitting stack is on the first light emitting stack, the second optical auxiliary layer has a thickness equal to or greater than about 400 angstroms and equal to or smaller than about 500 angstroms, the third optical auxiliary layer has a thickness equal to or greater than about 150 angstroms and equal to or smaller than about 250 angstroms, and a distance from the upper charge generation layer to the second electrode is equal to or greater than about 5150 angstroms and equal to or smaller than about 5350 angstroms.

16. The display device of claim 14, wherein the first light emitting stack is on the second light emitting stack, the second optical auxiliary layer has a thickness equal to or greater than about 400 angstroms and equal to or smaller than about 600 angstroms, the third optical auxiliary layer has a thickness equal to or greater than about 200 angstroms and equal to or smaller than about 400 angstroms, and a distance from the upper charge generation layer to the second electrode is equal to or greater than about 4350 angstroms and equal to or smaller than about 4450 angstroms.

17. The display device of claim 13, wherein the second light emitting stack is on the first light emitting stack, the first electrode comprises a first conductive layer, an optical auxiliary layer on the first conductive layer, and a second conductive layer on the optical auxiliary layer, the optical auxiliary layer comprises a first optical auxiliary layer overlapping the first pixel area and a second optical auxiliary layer overlapping the second pixel area, the first optical auxiliary layer has a thickness equal to or greater than about 200 angstroms and equal to or smaller than about 400 angstroms, the second optical auxiliary layer has a thickness equal to or greater than about 500 angstroms and equal to or smaller than about 700 angstroms, and a distance from the upper charge generation layer to the second electrode is equal to or greater than about 3850 angstroms and equal to or smaller than about 4150 angstroms.

18. The display device of claim 14, further comprising a color filter layer on the second electrode, wherein the color filter layer comprises a first color filter overlapping the first pixel area and to transmit a blue light, a second color filter overlapping the second pixel area and to transmit a green light, and a third color filter overlapping the third pixel area and to transmit a red light.

19. The display device of claim 7, wherein the first light emitting stack comprises a first light emitting layer, a first hole transport layer, and a first electron transport layer spaced from the first hole transport layer with the first light emitting layer interposed therebetween, the second light emitting stack comprises a second light emitting layer, a second hole transport layer, and a second electron transport layer spaced from the second hole transport layer with the second light emitting layer interposed therebetween, and the third light emitting stack comprises a third light emitting layer, a third hole transport layer, and a third electron transport layer spaced from the third hole transport layer with the third light emitting layer interposed therebetween.

20. The display device of claim 19, wherein the third hole transport layer has a thickness greater than a thickness of the second hole transport layer and has the thickness greater than a thickness of the first hole transport layer.

21. The display device of claim 7, wherein the light emitting element is to emit a white light.
